(19) United States
(12) Patent Application Publication
(10) Pub. No.: US 2026/0006973 A1
(43) Pub. Date: Jan. 1, 2026

(54) DISPLAY DEVICE, METHOD OF MANUFACTURING THE DISPLAY DEVICE, AND AN ELECTRONIC DEVICE INCLUDING THE DISPLAY DEVICE

(71) Applicant: Samsung Display Co., Ltd., Yongin-si (KR)

(72) Inventors: Se Hyun LEE, Yongin-si (KR); Sung Chul HONG, Yongin-si (KR); Do Yeong PARK, Yongin-si (KR)

(21) Appl. No.: 19/185,006

(22) Filed: Apr. 21, 2025

(30) Foreign Application Priority Data
Jun. 27, 2024 (KR) 10-2024-0084559

(51) Int. Cl. H10H 29/856; H10H 29/01; H10H 29/852

(52) U.S. Cl. CPC H10H 29/856; H10H 29/012; H10H 29/0363; H10H 29/852

(57) ABSTRACT

A display device includes first and second light emitting elements on a pixel circuit layer and spaced from each other, a first light extraction structure on the pixel circuit layer overlapping the first light emitting element in a plan view, a second light extraction structure on the pixel circuit layer overlapping the second light emitting element in a plan view, and spaced from the first light extraction structure, a cover layer covering the first and second light extraction structures and the pixel circuit layer, a first reflective layer surrounding a side surface of the first light extraction structure, and a second reflective layer surrounding a side surface of the second light extraction structure.

### CROSS-REFERENCE TO RELATED APPLICATION

The present application claims priority to and the benefit of Korean Patent Application No. 10-2024-0084559, filed on Jun. 27, 2024, in the Korean Intellectual Property Office, the entire content of which is incorporated herein by reference.

### BACKGROUND

### 1. Field

Embodiments of the present disclosure described herein are related to a display device, a method of manufacturing the display device, and an electronic device including the display device.

### 2. Description of the Related Art

A display device includes a pixel, which may include two or more sub-pixels. These sub-pixels of the pixel may be configured to emit light of various colors and luminances, depending on the combination of light emitted from each of the sub-pixels.

The information disclosed in this Background section is intended solely to enhance the understanding of the background of the disclosure and therefore it may contain information that does not constitute prior art.

### SUMMARY

Aspects according to one or more embodiments of the present disclosure are directed toward a display device capable of preventing or reducing light mixing between adjacent sub-pixels and improving light emission efficiency of each sub-pixel.

Aspects according to one or more embodiments of the present disclosure are directed toward a method of manufacturing the display device.

Additional aspects will be set forth in part in the description which follows and, in part, will be apparent from the description, or may be learned by practice of the presented embodiments of the disclosure.

According to one or more embodiments of the disclosure, a display device may include first and second light emitting elements arranged on a pixel circuit layer and spaced and/or apart (e.g., spaced apart or separated) from each other, a first light extraction structure arranged on the pixel circuit layer to overlap the first light emitting element in a plan view, a second light extraction structure arranged on the pixel circuit layer to overlap the second light emitting element in a plan view, and spaced and/or apart (e.g., spaced apart or separated) from the first light extraction structure, a cover layer covering the first and second light extraction structures and the pixel circuit layer, a first reflective layer arranged to be around (e.g., surround) a side surface of the first light extraction structure, and a second reflective layer arranged to be around (e.g., surround) a side surface of the second light extraction structure. The cover layer may be interposed between the first reflective layer and the side surface of the first light extraction structure. The cover layer may be interposed between the second reflective layer and the side surface of the second light extraction structure.

In one or more embodiments, the first reflective layer and the second reflective layer may be spaced and/or apart (e.g., spaced apart or separated) from each other.

In one or more embodiments, in a plan view, an edge of the first light extraction structure may completely be around (e.g., surround) an edge of the first light emitting element, and in a plan view, an edge of the second light extraction structure may completely be around (e.g., surround) an edge of the second light emitting element.

In one or more embodiments, the first light emitting element may be configured to generate light of a first color, and the second light emitting element may be configured to generate light of a second color different from the first color.

In one or more embodiments, the first light extraction structure may directly contact entire of a side surface of the first light emitting element and entire of an upper surface of the first light emitting element, and the second light extraction structure may directly contact entire of side surfaces of the second light emitting element and entire of an upper surface of the second light emitting element.

In one or more embodiments, the first light emitting element may include a (1-1)-th semiconductor layer, a (1-2)-th semiconductor layer arranged on the (1-1)-th semiconductor layer, and a first active layer interposed between the (1-1)-th semiconductor layer and the (1-2)-th semiconductor layer, and the second light emitting element may include a (2-1)-th semiconductor layer, a (2-2)-th semiconductor layer arranged on the (2-1)-th semiconductor layer, and a second active layer interposed between the (2-1)-th semiconductor layer and the (2-2)-th semiconductor layer.

In one or more embodiments, the display device may include a first anode electrode arranged between the first light emitting element and the pixel circuit layer, and a second anode electrode arranged between the second light emitting element and the pixel circuit layer.

In one or more embodiments, the first light extraction structure may be arranged to overlap the first anode electrode in a plan view, and the second light extraction structure may be arranged to overlap the second anode electrode in a plan view.

In one or more embodiments, the display device may further include a cathode electrode arranged between the first and second light emitting elements and the pixel circuit layer.

In one or more embodiments, the first light extraction structure may be arranged to overlap a portion of the cathode electrode in a plan view, and the second light extraction structure may be arranged to overlap another portion of the cathode electrode in a plan view.

In one or more embodiments, the first light extraction structure may include a first overcoating layer and a first light extraction layer arranged on the first overcoating layer, and the second light extraction structure may include a second overcoating layer and a second light extraction layer arranged on the second overcoating layer.

In one or more embodiments, the first overcoating layer may directly contact at least a portion of a lower surface of the first light emitting element, and the second overcoating layer may directly contact at least a portion of a lower surface of the second light emitting element.

In one or more embodiments, the display device may further include a third light emitting element arranged on the pixel circuit layer and spaced and/or apart (e.g., spaced apart or separated) from the first and second light emitting elements, a third light extraction structure arranged on the pixel circuit layer to overlap the third light emitting element in a plan view, and spaced and/or apart (e.g., spaced apart or separated) from the first and second light extraction structures, and a third reflective layer arranged to be around (e.g., surround) a side surface of the third light extraction structure. The cover layer may be interposed between the third reflective layer and the side surface of the third light extraction structure.

In one or more embodiments, a color of light generated by the third light emitting element may be different from a color of light generated by the first light emitting element and a color of light generated by the second light emitting element.

In one or more embodiments, the display device may further include a passivation layer arranged to cover the cover layer, the first reflective layer, and the second reflective layer, and a color filter layer arranged on the passivation layer.

In one or more embodiments, an upper surface of the passivation layer may be flat.

According to one or more embodiments of the present disclosure, a method of manufacturing a display device may include forming first and second light extraction structures overlapping the first and second light emitting elements in a plan view on a pixel circuit layer, and spaced and/or apart (e.g., spaced apart or separated) from each other, forming a cover layer covering the first and second light extraction structures and the pixel circuit layer, and forming first and second reflective layers arranged to be around (e.g., surround) side surfaces of the first and second light extraction structures. The cover layer may be interposed between the first reflective layer and the side surface of the first light extraction structure and between the second reflective layer and the side surface of the second light extraction structure.

In one or more embodiments, the forming of the first and second reflective layers may include forming a reflective layer covering the cover layer, and forming the first and second reflective layers by partially etching the reflective layer.

In one or more embodiments, the forming of the first and second light extraction structures may include forming the first and second light emitting elements spaced and/or apart (e.g., spaced apart or separated) from each other on the pixel circuit layer, forming an overcoating layer on the pixel circuit layer, forming a light extraction layer covering the first and second light emitting elements on the overcoating layer, and forming the first and second light extraction structures by partially etching the overcoating layer and the light extraction layer.

In one or more embodiments, in the forming of the overcoating layer, the first and second light emitting elements may be partially buried in the overcoating layer.

According to one or more embodiments of the present disclosure, an electronic device may include a processor to provide input image data, and a display device to display an image based on the input image data. The display device may include first and second light emitting elements arranged on a pixel circuit layer and spaced and/or apart (e.g., spaced apart or separated) from each other, a first light extraction structure arranged on the pixel circuit layer to overlap the first light emitting element in a plan view, a second light extraction structure arranged on the pixel circuit layer to overlap the second light emitting element in a plan view, and spaced and/or apart (e.g., spaced apart or separated) from the first light extraction structure, a cover layer covering the first and second light extraction structures and the pixel circuit layer, a first reflective layer arranged to be around (e.g., surround) a side surface of the first light extraction structure, and a second reflective layer arranged to be around (e.g., surround) a side surface of the second light extraction structure. The cover layer may be interposed between the first reflective layer and the side surface of the first light extraction structure. The cover layer may be interposed between the second reflective layer and the side surface of the second light extraction structure.

In the display device according to one or more embodiments of the present disclosure, the first and second reflective layers around (e.g., surrounding) the side surface of the first and second light extraction structures may be configured to allow the light emitted from the first and second light emitting elements to be emitted to a preset desired or suitable direction. Therefore, a display device with improved light emission efficiency may be provided.

In one or more embodiments, the first and second reflective layers may be configured to prevent or reduce light mixing in adjacent sub-pixels. Therefore, a display device capable of preventing or reducing light mixing between adjacent sub-pixels may be provided.

### BRIEF DESCRIPTION OF THE DRAWINGS

The above and other features of the disclosure will become more apparent by describing in further detail embodiments thereof with reference to the accompanying drawings, in which:

FIG. 1 is a block diagram illustrating a display device according to one or more embodiments of the present disclosure;

FIG. 2 is a block diagram illustrating one sub-pixel among sub-pixels included in the display device of FIG. 1;

FIG. 3 is a plan view illustrating a display panel configuring the display device of FIG. 1;

FIG. 4 is a cross-sectional view illustrating one or more embodiments of the display panel of FIG. 3;

FIG. 5 is a cross-sectional view illustrating one or more embodiments of the display panel of FIG. 3;

FIGS. 6 and 7 are plan views illustrating one or more embodiments of one pixel selected from among the pixels included in the display panel of FIG. 3;

FIG. 8 is a cross-sectional view taken along the line 11-11′ of FIG. 7;

FIG. 9 is a cross-sectional view taken along the line 12-12′ of FIG. 7;

FIG. 10 is a cross-sectional view taken along the line 13-13′ of FIG. 7;

FIG. 11 is a cross-sectional view taken along the line J1-J1′ of FIG. 7;

FIG. 12 is a diagram illustrating a method of manufacturing a display device including the pixel of FIGS. 6 and 7;

FIGS. 13-19 are cross-sectional views illustrating the manufacturing method of FIG. 12;

FIG. 20 is a block diagram illustrating a display system according to one or more embodiments; and

FIGS. 21-24 are perspective views illustrating application examples of the display system of FIG. 20.

### DETAILED DESCRIPTION

Hereinafter, one or more embodiments according to the present disclosure is described in more detail with reference to the accompanying drawings. It should be noted that in the following description, only portions necessary for understanding an operation according to the disclosure are described, and descriptions of other portions are not provided in order not to obscure the subject matter of the disclosure. In addition, the disclosure may be embodied in other forms without being limited to one or more embodiments described herein. However, one or more embodiments described herein are provided to describe in more detail enough to easily implement the technical spirit of the disclosure to those skilled in the art to which the disclosure belongs.

In the present specification, “including A or B”, “A and/or B”, etc., represents A or B, or A and B.

As used herein, the term “and/or” includes any and all combinations of one or more of the associated listed items. As used herein, expressions such as “at least one of”, “one of”, and “selected from”, when preceding a list of elements, modify the entire list of elements and do not modify the individual elements of the list. For example, “at least one of a, b or c”, “at least one selected from a, b and c”, etc., may indicate only a, only b, only c, both (e.g., simultaneously) a and b, both (e.g., simultaneously) a and c, both (e.g., simultaneously) b and c, all of a, b, and c, or variations thereof.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the disclosure. Throughout the specification, in a case where a certain portion “includes”, the case refers to that the portion may further include another component without excluding another component unless otherwise stated. “At least any one of X, Y, and Z” and “at least any one selected from among an array consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as first and second may be used to describe one or more suitable components, but these components are not limited to these terms. These terms are used to distinguish one component from another component. Therefore, a first component may refer to a second component within a range without departing from the scope disclosed herein.

Spatially relative terms such as “under”, “on”, and/or the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, if (e.g., when) a device shown in the drawing is turned upside down, elements depicted as being positioned “under” other elements or features are positioned in a direction “on” the other elements or features. Therefore, in one or more embodiments, the term “under” may include both (e.g., simultaneously) directions of on and under. In addition, the device may face in other directions (for example, rotated 90 degrees or in other directions) and thus the spatially relative terms used herein are interpreted according thereto.

One or more embodiments are described with reference to drawings schematically illustrating ideal embodiments. Accordingly, it will be expected that shapes may vary, for example, according to tolerances and/or manufacturing techniques. Therefore, one or more embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

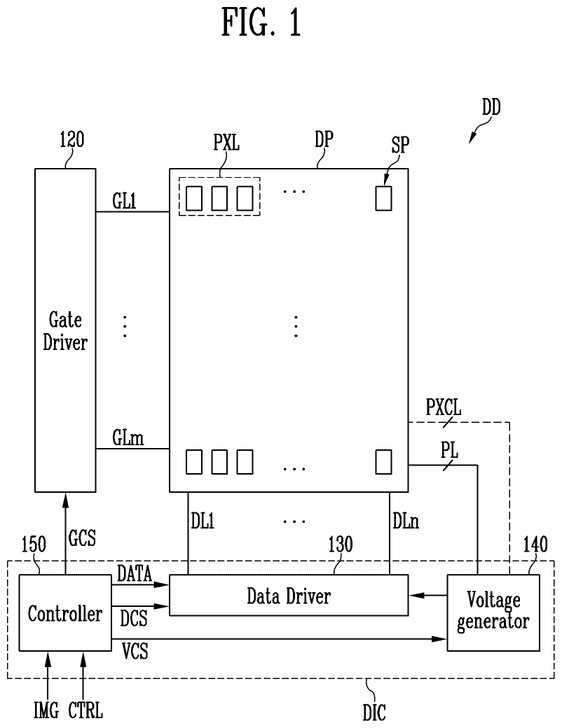

FIG. 1 is a block diagram illustrating a display device according to one or more embodiments of the present disclosure.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may be configured to generate light of two or more colors. For example, each of the sub-pixels SP may be configured to generate light such as red, green, blue, cyan, magenta, and/or yellow.

Two or more sub-pixels among the sub-pixels SP may configure one pixel PXL. That is, one pixel PXL may include two or more sub-pixels among the sub-pixels SP. For example, the pixel PXL may include three sub-pixels as shown in FIG. 1. The pixel PXL (e.g., the sub-pixels SP of the pixel PXL) may be configured to emit light of various colors and luminances according to a combination of light emitted from the sub-pixels (e.g., each of the sub-pixels) included in the pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In one or more embodiments, the gate control signal GCS may include a start signal indicating a start of each frame, a horizontal synchronization signal, and/or the like.

The gate driver 120 may be arranged on one side of the display panel DP. However, embodiments are not limited thereto. For example, the gate driver 120 may be divided into two or more physically and/or logically divided drivers, and such drivers may be arranged on one side of the display panel DP and another side of the display panel DP opposite the one side. As described above, the gate driver 120 may be arranged around the display panel DP in one or more suitable shapes according to one or more embodiments.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In one or more embodiments, the data control signal DCS may include a source start signal, a source shift clock, a source output enable signal, and/or the like.

The data driver 130 may receive voltages from the voltage generator 140. The data driver 130 may apply data signals having grayscale voltages corresponding to the image data DATA to the first to n-th data lines DL1 to DLn using the received voltages. When the gate signal is applied to each of the first to m-th gate lines GL1 to GLm, the data signals corresponding to the image data DATA may be applied to the data lines DL1 to DLn. Accordingly, the sub-pixels SP may generate light corresponding to the data signals, and the display panel DP may display an image.

In one or more embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device DD, such as the gate driver 120, the data driver 130, and the controller 150. The voltage generator 140 may generate the plurality of voltages by receiving an input voltage from an outside of the display device DD and regulating the received voltage.

The voltage generator 140 may generate a first power voltage and a second power voltage. The generated first and second power voltages may be provided to the sub-pixels SP through power lines PL. In one or more embodiments, at least one of (e.g., selected from among) the first and second power voltages may be provided from the outside of the display device DD.

In addition, the voltage generator 140 may provide one or more suitable voltages and/or signals. For example, the voltage generator 140 may provide one or more initialization voltages applied to the sub-pixels SP. For example, during a sensing operation for sensing electrical characteristics of transistors and/or light emitting elements of the sub-pixels SP, a set or predetermined reference voltage may be applied to the first to n-th data lines DL1 to DLn, and the voltage generator 140 may generate the reference voltage and transmit the reference voltage to the data driver 130. For example, during a display operation for displaying an image on the display panel DP, common pixel control signals may be applied to the sub-pixels SP, and the voltage generator 140 may generate the pixel control signals. In one or more embodiments, the voltage generator 140 may provide the pixel control signals to the sub-pixels SP through pixel control lines PXCL. In FIG. 1, the pixel control lines PXCL are connected between the voltage generator 140 and the display panel DP, but embodiments are not limited thereto. For example, the pixel control lines PXCL may be connected between the gate driver 120 and the display panel DP. In this case, the pixel control signals may be transmitted from the voltage generator 140 to the pixel control lines PXCL through the gate driver 120.

The controller 150 may control overall operations of the display device DD. The controller 150 may receive input image data IMG and a control signal CTRL corresponding thereto from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device DD or the display panel DP and output the image data DATA. In one or more embodiments, the controller 150 may output the image data DATA by aligning the input image data IMG so that the input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. That is, the data driver 130, the voltage generator 140, and the controller 150 may be separate from each other and in one driver integrated circuit DIC. In one or more embodiments, at least one of the data driver 130, the voltage generator 140, and the controller 150 may be provided as a component distinguished from the driver integrated circuit DIC.

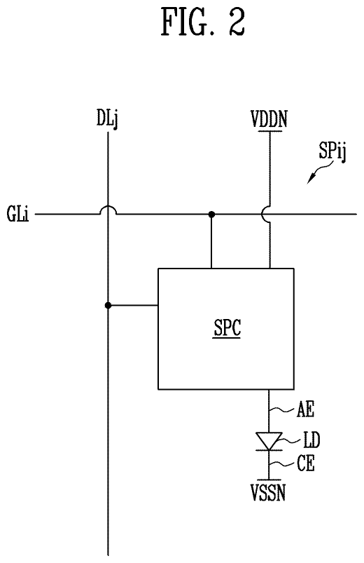

FIG. 2 is a block diagram illustrating one sub-pixel among the sub-pixels included in the display device of FIG. 1. In FIG. 2, among the sub-pixels SP of FIG. 1, a sub-pixel SPij arranged in an i-th row (i is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL of FIG. 1 and receives the first power voltage. The second power voltage node VSSN may be connected to another one of the power lines PL of FIG. 1 and receives the second power voltage. The first power voltage may have a voltage level higher than that of the second power voltage.

The light emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD may be configured to emit light according to a current flowing from the anode electrode AE to the cathode electrode CE.

The sub-pixel circuit SPC may be connected to an i-th gate line GLi among the first to m-th gate lines GL1 to GLm of FIG. 1, and a j-th data line DLj among the first to n-th data lines DL1 to DLn of FIG. 1. In response to a gate signal received through the i-th gate line GLi, the sub-pixel circuit SPC may control the light emitting element LD to emit light according to a data signal received through the j-th data line DLj. In one or more embodiments, the sub-pixel circuit SPC may be further connected to the pixel control lines PXCL of FIG. 1. In this case, the sub-pixel circuit SPC may control the light emitting element LD in further response to the pixel control signals received through the pixel control lines PXCL.

For such operations, the sub-pixel circuit SPC may include circuit elements, for example, transistors and one or more capacitors.

The transistors of the sub-pixel circuit SPC may include P-type (kind) transistors and/or N-type (kind) transistors. In one or more embodiments, the transistors of the sub-pixel circuit SPC may include a metal oxide silicon field effect transistor (MOSFET). In one or more embodiments, the transistors of the sub-pixel circuit SPC may include an amorphous silicon semiconductor, a monocrystalline silicon semiconductor, a polycrystalline silicon semiconductor, an oxide semiconductor, and/or the like.

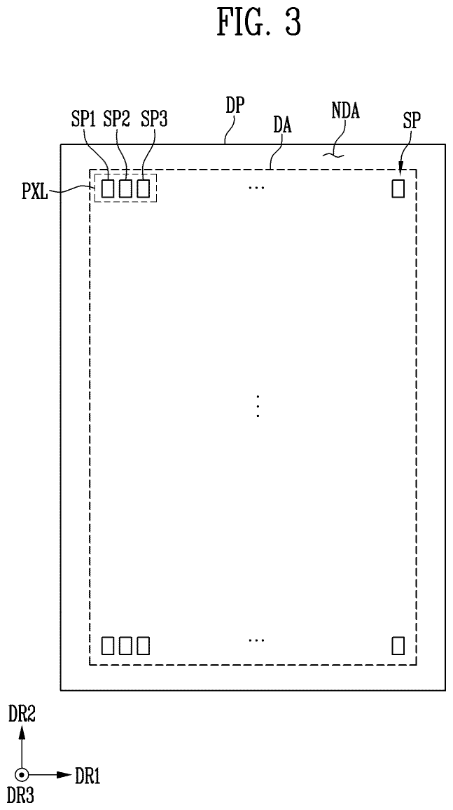

FIG. 3 is a plan view illustrating the display panel configuring the display device of FIG. 1.

Referring to FIG. 3, the display panel DP may include a display area DA and a non-display area NDA. The display panel DP may display an image through the display area DA. The non-display area NDA may be arranged around the display area DA.

The display panel DP may include the sub-pixels SP in the display area DA. The sub-pixels SP may be arranged along a first direction DR1 and a second direction DR2 crossing the first direction DR1. For example, the sub-pixels SP may be arranged in a matrix form along the first direction DR1 and the second direction DR2. As another example, the sub-pixels SP may be arranged in a zigzag form along the first direction DR1 and the second direction DR2. An arrangement of the sub-pixels SP may vary according to one or more embodiments. The first direction DR1 may be a column direction, and the second direction DR2 may be a row direction.

Two or more sub-pixels among the plurality of sub-pixels SP may configure one pixel PXL. That is, one pixel PXL may include two or more sub-pixels among the plurality of sub-pixels SP. In FIG. 3, the pixel PXL includes three sub-pixels SP1, SP2, and SP3, but embodiments are not limited thereto. For example, the pixel PXL may include two sub-pixels. Hereinafter, for convenience of description, it is assumed that the pixel PXL includes the first to third sub-pixels SP1, SP2, and SP3.

Each of the first to third sub-pixels SP1, SP2, and SP3 may generate light of one of one or more suitable colors such as red, green, blue, cyan, magenta, and yellow. Hereinafter, for clear and concise description, it is assumed that the first sub-pixel SP1 is configured to generate light of a red color (first color), the second sub-pixel SP2 is configured to generate light of a green color (second color), and the third sub-pixel SP3 is configured to generate light of a blue color (third color).

Each of the first to third sub-pixels SP1, SP2, and SP3 may include at least one light emitting element configured to generate light. In one or more embodiments, the light emitting elements of the first to third sub-pixels SP1, SP2, and SP3 may be configured to generate light of different colors. For example, the light emitting elements of the first to third sub-pixels SP1, SP2, and SP3 may be configured to generate red, green, and blue light, respectively.

As the display panel DP, a display panel capable of self-emission, such as a light emitting diode display panel (LED display panel) using a micro scale or nano scale of light emitting diode as the light emitting element, an organic light emitting display panel (OLED panel) using an organic light emitting diode as the light emitting element, and/or the like, may be used.

Component for controlling the sub-pixels SP may be arranged in the non-display area NDA. Lines connected to the sub-pixels SP, for example, the first to m-th gate lines GL1 to GLm of FIG. 1, the first to n-th data lines DL1 to DLn, the power lines PL, and the pixel control lines PXCL may be arranged in the non-display area NDA.

At least one of the gate driver 120, the data driver 130, the voltage generator 140, or the controller 150 of FIG. 1 may be arranged in the non-display area NDA of the display panel DP. In one or more embodiments, the gate driver 120 may be arranged in the non-display area NDA. In this case, the data driver 130, the voltage generator 140, and the controller 150 may be implemented as a driver integrated circuit DIC of FIG. 1, separate from the display panel DP, and the driver integrated circuit DIC may be connected to the lines arranged in the non-display area NDA. In one or more embodiments, the gate driver 120 may be implemented as one integrated circuit separate from the display panel DP, together with the data driver 130, the voltage generator 140, and the controller 150.

In one or more embodiments, the display area DA may have one or more suitable shapes. The display area DA may have a closed loop shape including sides of a straight line and/or a curved line. For example, the display area DA may have shapes of a polygon, a circle, a semicircle, an ellipse, and/or the like.

In one or more embodiments, the display panel DP may have a flat display surface. In one or more embodiments, the display panel DP may have a display surface that is at least partially round.

In one or more embodiments, the display panel DP may be bendable, foldable, or rollable. In such cases, the display panel DP and/or a substrate of the display panel DP may include materials having a flexible property.

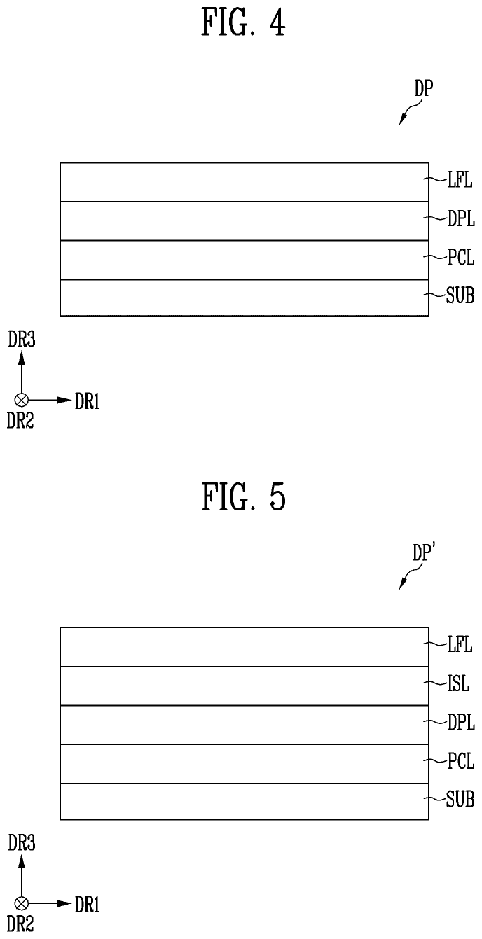

FIG. 4 is a cross-sectional view illustrating one or more embodiments of the display panel of FIG. 3.

Referring to FIG. 4, the display panel DP may include a substrate SUB, and a pixel circuit layer PCL, a display element layer DPL, and a light functional layer LFL sequentially stacked on the substrate SUB in a third direction DR3 crossing the first and second directions DR1 and DR2.

The substrate SUB may be formed of an insulating material such as glass or resin. For example, the substrate SUB may include a glass substrate. As another example, the substrate SUB may include a polyimide (PI) substrate. As still another example, the substrate SUB may include a silicon wafer substrate formed using a semiconductor process.

In one or more embodiments, the substrate SUB may be formed of a flexible material that may be bent or folded, and may have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be arranged on the substrate SUB. The pixel circuit layer PCL may include insulating layers and semiconductor patterns and conductive patterns arranged between the insulating layers. The conductive patterns of the pixel circuit layer PCL may function as circuit elements, lines, and/or the like.

The circuit elements of the pixel circuit layer PCL may include the sub-pixel circuit SPC (refer to FIG. 2) of each of the sub-pixels SP of FIG. 3. For example, the circuit elements of the pixel circuit layer PCL may be provided as transistors and one or more capacitors of the sub-pixel circuit SPC.

The lines of the pixel circuit layer PCL may include lines connected to the sub-pixels SP. The lines of the pixel circuit layer PCL may include one or more suitable signal lines and/or voltage lines necessary to drive the display element layer DPL.

The display element layer DPL may be arranged on the pixel circuit layer PCL. The display element layer DPL may include light emitting elements of the sub-pixels SP.

The light functional layer LFL may be arranged on the display element layer DPL. The light functional layer LFL may include light conversion patterns having color conversion particles and/or scattering particles. For example, the color conversion particles may include quantum dots. The quantum dots may change a wavelength (or color) of light emitted from the display element layer DPL. The light functional layer LFL may further include light scattering patterns having the scattering particles. In one or more embodiments, the light conversion patterns and the light scattering patterns may not be provided.

The light functional layer LFL may include a color filter layer including color filters. The color filter may be configured to selectively transmit light of a specific wavelength (or a specific color). In one or more embodiments, the color filter layer may not be provided.

A window for protecting an exposed surface (or an upper surface) of the display panel DP may be provided on the light functional layer LFL. The window may protect the display panel DP from external shock. The window may be coupled to the light functional layer LFL through an optically transparent adhesive (or cohesive) member. The window may have a multi-layer structure selected from among a glass substrate, a plastic film, and a plastic substrate. The multi-layer structure may be formed through a substantially continuous process or an adhesion process using an adhesive layer. All or a portion of the window may be flexible.

FIG. 5 is a cross-sectional view illustrating one or more embodiments of the display panel of FIG. 3.

Referring to FIG. 5, the display panel DP′ may include the substrate SUB, the pixel circuit layer PCL, the display element layer DPL, an input sensing layer ISL, and the light functional layer LFL. The substrate SUB, the pixel circuit layer PCL, the display element layer DPL, and the light functional layer LFL may be configured similarly to the substrate SUB, the pixel circuit layer PCL, the display element layer DPL, and the light functional layer LFL described with reference to FIG. 4, respectively. Hereinafter, an overlapping description may not be provided.

The input sensing layer ISL may sense a user's input on an upper surface (or a display surface) of the display panel DP′. The input sensing layer ISL may include components suitable for sensing an external object such as a user's hand, or a pen. For example, the input sensing layer ISL may include touch electrodes.

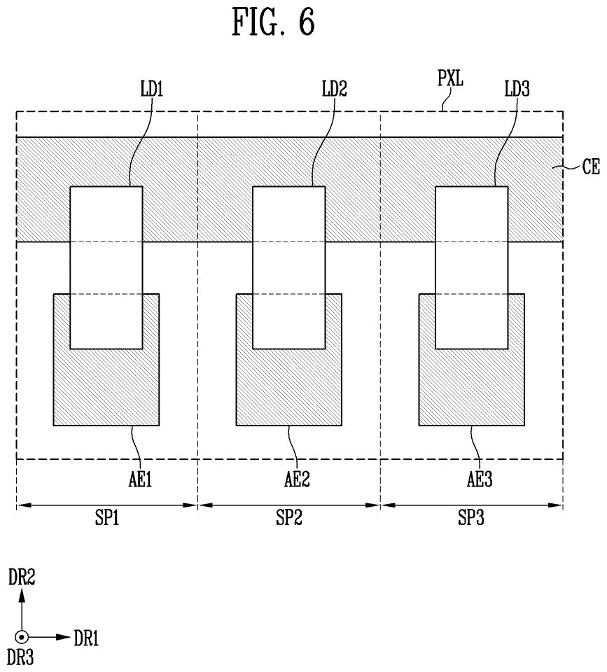

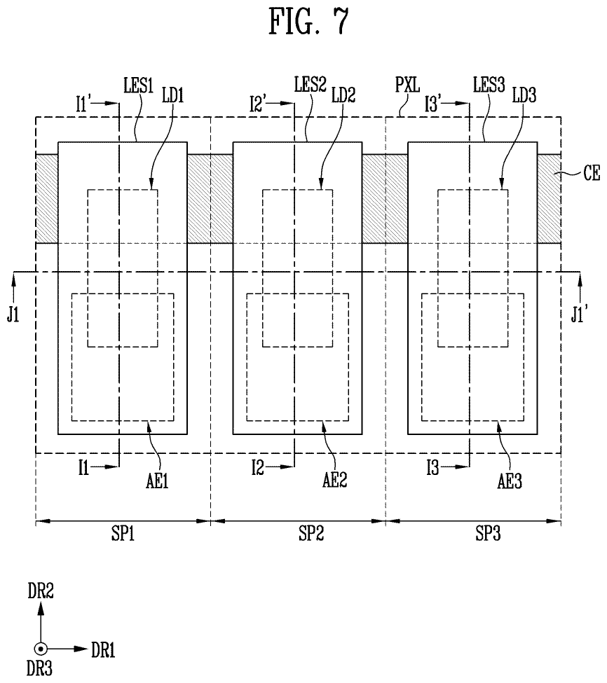

FIGS. 6 and 7 are plan views illustrating one or more embodiments of one pixel among the pixels included in the display panel of FIG. 3.

Referring to FIG. 6, the pixel PXL may include the first to third sub-pixels SP1, SP2, and SP3. The first to third sub-pixels SP1, SP2, and SP3 may be arranged in the first direction DR1. However, an arrangement of the first to third sub-pixels SP1, SP2, and SP3 is not limited thereto and may variously change according to one or more embodiments. For example, the first to third sub-pixels SP1, SP2, and SP3 may be arranged in a zigzag.

First to third anode electrodes AE1, AE2, and AE3 may be arranged in the first to third sub-pixels SP1, SP2, and SP3, respectively. The first anode electrode AE1 may be provided as the anode electrode AE (refer to FIG. 2) connected to the sub-pixel circuit SPC (refer to FIG. 2) of the first sub-pixel SP1. The second anode electrode AE2 may be provided as the anode electrode AE connected to the sub-pixel circuit SPC of the second sub-pixel SP2. The third anode electrode AE3 may be provided as the anode electrode AE connected to the sub-pixel circuit SPC of the third sub-pixel SP3.

The cathode electrode CE may be spaced and/or apart (e.g., spaced apart or separated) from the first to third anode electrodes AE1, AE2, and AE3. The cathode electrode CE may be arranged in substantially the same layer as the first to third anode electrodes AE1, AE2, and AE3. The cathode electrode CE may be spaced and/or apart (e.g., spaced apart or separated) from the first to third anode electrodes AE1, AE2, and AE3 in the second direction DR2.

In one or more embodiments, the cathode electrode CE may extend in the first direction DR1 and may be used as a common electrode for the pixel PXL and other pixels adjacent to the pixel PXL. In one or more embodiments, the cathode electrode CE may be extended not only in the first direction DR1 but also in the second direction DR2 and may be used as the common electrode for all of the sub-pixels SP of FIG. 3. That is, the cathode electrode CE may be used as the common electrode for the first to third sub-pixels SP1, SP2, and SP3. As described above, the cathode electrode CE may have one or more suitable shapes.

First to third light emitting elements LD1, LD2, and LD3 may be arranged on the first to third anode electrodes AE1, AE2, and AE3 and the cathode electrode CE. The first light emitting element LD1 may be electrically connected to the first anode electrode AE1 and the cathode electrode CE. The first light emitting element LD1 may be provided as the light emitting element LD (see FIG. 2) connected to the sub-pixel circuit SPC of the first sub-pixel SP1. The second light emitting element LD2 may be electrically connected to the second anode electrode AE2 and the cathode electrode CE. The second light emitting element LD2 may be provided as the light emitting element LD connected to the sub-pixel circuit SPC of the second sub-pixel SP2. The third light emitting element LD3 may be electrically connected to the third anode electrode AE3 and the cathode electrode CE. The third light emitting element LD3 may be provided as the light emitting element LD connected to the sub-pixel circuit SPC of the third sub-pixel SP3.

The first light emitting element LD1, the second light emitting element LD2, and the third light emitting element LD3 may be inorganic light emitting diodes including an inorganic light emitting material. However, embodiments are not limited thereto. For example, organic light emitting diodes may be used.

Referring to FIG. 7, first to third light extraction structures LES1, LES2, and LES3 may be arranged in the first to third sub-pixels SP1, SP2, and SP3, respectively.

The first light extraction structure LES1 may overlap the first light emitting element LD1 on a plane (e.g., in a plan view). In this case, an edge of the first light extraction structure LES1 may completely be around (e.g., surround) an edge of the first light emitting element LD1 on a plane (e.g., in a plan view). In one or more embodiments, the first light extraction structure LES1 may overlap the first anode electrode AE1 on a plane (e.g., in a plan view). In this case, on a plane (e.g., in a plan view), the edge of the first light extraction structure LES1 may completely be around (e.g., surround) an edge of the first anode electrode AE1. In the context of the present patent application and unless define other, “a plan view” refers to how a structure (e.g. the first light extraction structure LES1) overlaps with another structure or structures (e.g., the first light-emitting element LD1 and the first anode electrode AE1) when viewed from above. This helps to visualize the positioning and alignment of these components on a flat plane.

The second light extraction structure LES2 may be spaced and/or apart (e.g., spaced apart or separated) from the first light extraction structure LES1. The second light extraction structure LES2 may overlap the second light emitting element LD2 on a plane (e.g., in a plan view). In this case, an edge of the second light extraction structure LES2 may completely be around (e.g., surround) an edge of the second light emitting element LD2 on a plane (e.g., in a plan view). In one or more embodiments, the second light extraction structure LES2 may overlap the second anode electrode AE2 on a plane (e.g., in a plan view). In this case, on a plane (e.g., in a plan view), the edge of the second light extraction structure LES2 may completely be around (e.g., surround) an edge of the second anode electrode AE2.

The third light extraction structure LES3 may be spaced and/or apart (e.g., spaced apart or separated) from the first and second light extraction structures LES1 and LES2. The third light extraction structure LES3 may overlap the third light emitting element LD3 on a plane (e.g., in a plan view). In this case, an edge of the third light extraction structure LES3 may completely be around (e.g., surround) an edge of the third light emitting element LD3 on a plane (e.g., in a plan view). In one or more embodiments, the third light extraction structure LES3 may overlap the third anode electrode AE3 on a plane (e.g., in a plan view). In this case, on a plane (e.g., in a plan view), the edge of the third light extraction structure LES3 may completely be around (e.g., surround) an edge of the third anode electrode AE3.

In one or more embodiments, each of the first to third light extraction structures LES1, LES2, and LES3 may partially overlap the cathode electrode CE on a plane (e.g., in a plan view). The first light extraction structure LES1 may overlap a portion of the cathode electrode CE on a plane (e.g., in a plan view). The second light extraction structure LES2 may overlap another portion of the cathode electrode CE on a plane (e.g., in a plan view). The third light extraction structure LES3 may overlap still another portion of the cathode electrode CE on a plane (e.g., in a plan view).

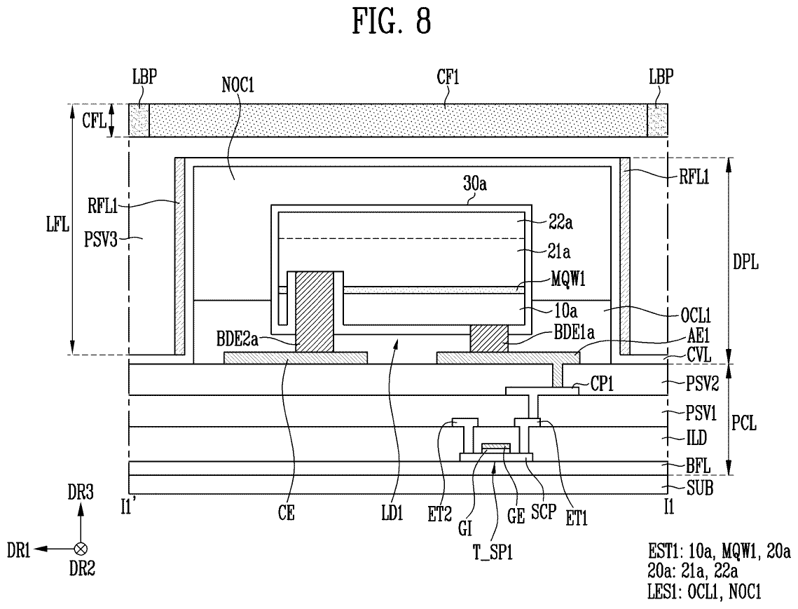

FIG. 8 is a cross-sectional view taken along the line 11-11′ of FIG. 7. FIG. 8 is a cross-sectional view illustrating the first sub-pixel.

Referring to FIGS. 6 to 8, the pixel circuit layer PCL, the display element layer DPL, and the light functional layer LFL may be sequentially arranged on the substrate SUB.

The pixel circuit layer PCL may include insulating layers, semiconductor patterns, and conductive patterns stacked on the substrate SUB. The insulating layers may include a buffer layer BFL, one or more interlayer insulating layers ILD, and one or more passivation layers PSV1 and PSV2. Semiconductor patterns and conductive patterns may be positioned between the insulating layers. The conductive patterns may include at least one material selected from among copper (Cu), molybdenum (Mo), tungsten (W), aluminum neodymium (AlNd), titanium (Ti), aluminum (Al), and silver (Ag).

As described with reference to FIG. 2, the sub-pixel circuit SPC (refer to FIG. 2) of each of the first to third sub-pixels SP1, SP2, and SP3 may include transistors and one or more capacitors. The semiconductor patterns and the conductive patterns of the pixel circuit layer PCL may function as transistors and capacitors of the sub-pixel circuit SPC. In addition, the conductive patterns of the pixel circuit layer PCL may further function as lines, for example, the first to m-th gate lines GL1 to GLm of FIG. 1, the first to n-th data lines DL1 to DLn, and the power lines PL, and the pixel control lines PXCL.

The buffer layer BFL may be arranged on one surface of the substrate SUB. The buffer layer BFL may prevent or reduce an impurity from diffusing into circuit elements and lines included in the pixel circuit layer PCL. The buffer layer BFL may include an inorganic insulating layer including an inorganic material. In one or more embodiments, the buffer layer BFL may include at least one of metal oxides such as silicon nitride, silicon oxide, silicon oxynitride, and aluminum oxide. The buffer layer BFL may be provided as a single layer or multiple layers. When the buffer layer BFL is provided as multiple layers, each layer may be formed of the same material or may be formed of different materials.

In one or more embodiments, one or more barrier layers may be arranged between the substrate SUB and the buffer layer BFL. Each of the barrier layers may include polyimide.

A first transistor T_SP1 may be arranged on the buffer layer BFL. The first transistor T_SP1 may be one of the transistors of the sub-pixel circuit SPC included in the first sub-pixel SP1. The first transistor T_SP1 may be a transistor connected to the first anode electrode AE1 among the transistors of the sub-pixel circuit SPC.

The first transistor T_SP1 may include a semiconductor pattern SCP, a gate electrode GE, a first terminal ET1, and a second terminal ET2. The first terminal ET1 may be one of a source electrode and a drain electrode, and the second terminal ET2 may be the other one of the source electrode and the drain electrode. For example, the first terminal ET1 may be the source electrode, and the second terminal ET2 may be the drain electrode.

The semiconductor pattern SCP may be arranged on the buffer layer BFL. The semiconductor pattern SCP may include a first contact area contacting the first terminal ET1 and a second contact area contacting the second terminal ET2. An area between the first contact area and the second contact area may be a channel area. The channel area may overlap the gate electrode GE of the first transistor T_SP1. The channel area may be a semiconductor pattern that is not doped with an impurity and may be an intrinsic semiconductor. The first contact area and the second contact area may be a semiconductor pattern doped with an impurity. As the impurity, for example, a p-type (kind) impurity may be used, but embodiments are not limited thereto.

The semiconductor pattern SCP may include one of one or more suitable types (kinds) of semiconductors, for example, an amorphous silicon semiconductor, a monocrystalline silicon semiconductor, a polycrystalline silicon semiconductor, a low temperature poly silicon semiconductor, and an oxide semiconductor.

Interlayer insulating layers ILD sequentially stacked on the semiconductor pattern SCP may be arranged. The interlayer insulating layers ILD may be inorganic insulating layers including an inorganic material. For example, each of the interlayer dielectric layers ILD may include at least one of metal oxides such as silicon nitride, silicon oxide, silicon oxynitride, and aluminum oxide. However, the interlayer insulating layers ILD are not limited thereto. For example, one of the interlayer dielectric layers ILD may include an organic insulating layer including an organic material.

The interlayer insulating layers ILD may electrically separate conductive patterns and/or semiconductor patterns arranged between the interlayer insulating layers ILD from each other. For example, the interlayer insulating layers ILD may include a gate insulating layer GI arranged on the semiconductor pattern SCP. The gate insulating layer GI may be arranged between the semiconductor pattern SCP and the gate electrode GE so that the gate electrode GE is spaced and/or apart (e.g., spaced apart or separated) from the semiconductor pattern SCP. In one or more embodiments, the gate insulating layer GI may be provided entirely on the semiconductor pattern SCP and the buffer layer BFL to cover the semiconductor pattern SCP and the buffer layer BFL. As the number of layers desired or required to form the conductive patterns and/or the semiconductor patterns increases, the number of interlayer insulating layers ILD may increase.

The gate electrode GE may be arranged on the gate insulating layer GI. The gate electrode GE may overlap the channel area of the semiconductor pattern SCP. In one or more embodiments, the gate electrode GE may be provided as a single layer including at least one of copper (Cu), molybdenum (Mo), tungsten (W), aluminum neodymium (AlNd), titanium (Ti), aluminum (Al), or silver (Ag). In one or more embodiments, the gate electrode GE may be provided as multiple layers including at least one of molybdenum (Mo), titanium (Ti), copper (Cu), aluminum (Al), or silver (Ag) which is a low-resistance material.

The first and second terminals ET1 and ET2 may be arranged on the interlayer insulating layers ILD. The first and second terminals ET1 and ET2 may contact the semiconductor pattern SCP through contact holes passing through the interlayer insulating layers ILD. The first and second terminals ET1 and ET2 may respectively contact the first and second contact areas of the semiconductor pattern SCP. In one or more embodiments, the first and second contact areas of the semiconductor pattern SCP may be spaced and/or apart (e.g., spaced apart or separated) from each other in a first direction DR1. In one or more embodiments, the first and second contact areas of the semiconductor pattern SCP may be at opposite sides of the semiconductor pattern SCP. Each of the first and second terminals ET1 and ET2 may include at least one material selected from among copper (Cu), molybdenum (Mo), tungsten (W), aluminum neodymium (AlNd), titanium (Ti), aluminum (Al), and silver (Ag).

In one or more embodiments, the first transistor T_SP1 may be a low temperature polysilicon transistor. However, embodiments are not limited thereto. For example, the first transistor T_SP1 may be configured of an oxide semiconductor transistor. In one or more embodiments, the sub-pixel circuit of the first sub-pixel SP1 may include different types (kinds) of transistors. For example, the first transistor T_SP1 may be configured of a low temperature polysilicon transistor, and another transistor of the first sub-pixel SP1 may be configured of an oxide semiconductor transistor. In this case, an oxide semiconductor of the corresponding oxide semiconductor transistor may be arranged on one of the interlayer insulating layers ILD rather than the insulating layer where the semiconductor pattern SCP of the first transistor T_SP1 is arranged.

In one or more embodiments, a case where the first transistor T_SP1 is a transistor of a top gate structure is described as an example, but embodiments are not limited thereto. For example, the first transistor T_SP1 may be a transistor of a bottom gate structure. In addition, a structure of the first transistor T_SP1 may be variously changed.

At least a portion of one or more suitable lines of the display panel DP and/or the display device DD may be further arranged on the interlayer insulating layers ILD.

A first passivation layer PSV1 may be arranged on the interlayer insulating layers ILD and the first and second terminals ET1 and ET2. A passivation layer may also be referred to as a protective layer or a via layer. The first passivation layer PSV1 may protect components arranged thereunder and may provide a flat upper surface.

A first connection pattern CP1 may be arranged on the first passivation layer PSV1. The first connection pattern CP1 may pass through the first passivation layer PSV1 and may be connected to the first terminal ET1 of the first transistor T_SP1. The first connection pattern CP1 may include at least one material selected from among copper (Cu), molybdenum (Mo), tungsten (W), aluminum neodymium (AlNd), titanium (Ti), aluminum (Al), and silver (Ag).

At least a portion of the one or more suitable lines of the display panel DP and/or the display device DD may be further arranged on the first passivation layer PSV1.

A second passivation layer PSV2 may be arranged on the first connection pattern CP1 and the first passivation layer PSV1. The second passivation layer PSV2 may protect components arranged thereunder and may provide a flat upper surface.

Each of the first and second passivation layers PSV1 and PSV2 may include an inorganic insulating layer including an inorganic material and/or an organic insulating layer including an organic material. The inorganic insulating layer may include, for example, at least one of metal oxides such as silicon oxide, silicon nitride, silicon oxynitride, and aluminum oxide. The organic insulating layer may include, for example, at least one of acrylic resin, epoxy resin, phenol resin, polyamide resin, polyimide resin, unsaturated polyester resin, poly-phenylene ether resin, poly-phenylene sulfide resin, or benzocyclobutene resin.

The first and second passivation layers PSV1 and PSV2 may include the same material as one of the interlayer insulating layers ILD, but embodiments are not limited thereto. Each of the first and second passivation layers PSV1 and PSV2 may be provided as a single layer, but may also be provided as multiple layers.

The display element layer DPL may be arranged on the second passivation layer PSV2. The display element layer DPL may include the first anode electrode AE1, the cathode electrode CE, the first light emitting element LD1, the first light extraction structure LES1, a cover layer CVL, and a first reflective layer RFL1.

The first anode electrode AE1 may be arranged on the pixel circuit layer PCL. The first anode electrode AE1 may be electrically connected to the first connection pattern CP1 through a contact hole passing through the second passivation layer PSV2. As described above, the first anode electrode AE1 may be electrically connected to the first transistor T_SP1.

The cathode electrode CE may be arranged on the pixel circuit layer PCL. The cathode electrode CE may be spaced and/or apart (e.g., spaced apart or separated) from the first anode electrode AE1. The cathode electrode CE may be electrically connected to the second power voltage node VSSN of FIG. 2. Accordingly, the second power voltage applied to the second power voltage node VSSN may be transmitted to the cathode electrode CE.

The first light emitting element LD1 may be arranged on the first anode electrode AE1 and the cathode electrode CE. The first light emitting element LD1 may include a first light emitting stack EST1, a (1-1)-th bonding electrode BDE1a, a (1-2)-th bonding electrode BDE2a, and a first insulating layer 30a.

The first light emitting stack EST1 may be configured to be suitable for emitting the light of the first color. The first light emitting stack EST1 may include a (1-1)-th semiconductor layer 10a, a first active layer MQW1, and a (1-2)-th semiconductor layer 20a.

The (1-1)-th semiconductor layer 10a may be configured to provide a hole. The (1-1)-th semiconductor layer 10a may have a first polarity. For example, the (1-1)-th semiconductor layer 10a may include at least one p-type (kind) semiconductor layer. For example, the (1-1)-th semiconductor layer 10a may include at least one semiconductor material selected from among gallium nitride (GaN), aluminum gallium nitride (AlGaN), indium gallium nitride (InGaN), aluminum nitride (AlN), and indium nitride (InN), and may be a p-type (kind) semiconductor layer doped with a first conductive dopant (or a p-type (kind) dopant) such as magnesium (Mg), zinc (Zn), calcium (Ca), strontium (Sr), and barium (Ba). However, a material configuring the (1-1)-th semiconductor layer 10a is not limited thereto, and one or more suitable other materials may configure the (1-1)-th semiconductor layer 10a. In one or more embodiments of the disclosure, the (1-1)-th semiconductor layer 10a may include a gallium nitride (GaN) semiconductor material doped with the first conductive dopant (or the p-type (kind) dopant).

The first active layer MQW1 may be arranged on the (1-1)-th semiconductor layer 10a. The first active layer MQW1 may be interposed between the (1-1)-th semiconductor layer 10a and the (1-2)-th semiconductor layer 20a to provide an area where an electron and a hole recombine. As the electron and the hole recombine in the first active layer MQW1, the electron and the hole may transition to a low energy level, and thus light having a wavelength corresponding thereto may be generated. The first active layer MQW1 may be formed as a single or multiple quantum well structure. When the first active layer MQW1 is formed as the multiple quantum well structure, a unit including a barrier layer, a strain reinforcement layer, and a well layer may be repeatedly stacked to form the first active layer MQW1. However, the first active layer MQW1 is not limited to the structure described above.

In one or more embodiments, the first active layer MQW1 may be configured to emit the light of the first color (for example, red). In this case, the first active layer MQW1 may include a material suitable for emitting the light of the first color.

The (1-2)-th semiconductor layer 20a may be arranged on the first active layer MQW1. The (1-2)-th semiconductor layer 20a may include a first doping layer 21a and a first auxiliary layer 22a arranged on the first doping layer 21a.

The first doping layer 21a may be arranged on the first active layer MQW1. The first doping layer 21a may be configured to provide an electron. The first doping layer 21a may have a second polarity different from the first polarity. For example, the first doping layer 21a may include at least one n-type (kind) semiconductor layer. For example, the first doping layer 21a may include at least one semiconductor material selected from among gallium nitride (GaN), aluminum gallium nitride (AlGaN), indium gallium nitride (InGaN), aluminum nitride (AlN), and indium nitride (InN), and may be an n-type (kind) semiconductor layer doped with a second conductive dopant (or an n-type (kind) dopant) such as silicon (Si), germanium (Ge), and tin (Sn). However, a material configuring the first doping layer 21a is not limited thereto, and one or more suitable other materials may configure the first doping layer 21a. In one or more embodiments of the disclosure, the first doping layer 21a may include a gallium nitride (GaN) semiconductor material doped with the second conductive dopant (or the n-type (kind) dopant).

The first auxiliary layer 22a may include a gallium nitride (GaN) semiconductor material that is not substantially doped with an impurity or is doped with an impurity at a relatively low concentration. The first auxiliary layer 22a may configure an n-type (kind) semiconductor layer together with the first doping layer 21a.

The (1-1)-th bonding electrode BDE1a may be bonded and fixed on the first anode electrode AE1. The (1-1)-th bonding electrode BDE1a may be connected to the (1-1)-th semiconductor layer 10a and the first anode electrode AE1. The (1-1)-th semiconductor layer 10a and the first anode electrode AE1 may be electrically connected through the (1-1)-th bonding electrode BDE1a. In one or more embodiments, the (1-1)-th bonding electrode BDE1a may include a eutectic metal.

The (1-2)-th bonding electrode BDE2a may be bonded and fixed on the cathode electrode CE. The (1-2)-th bonding electrode BDE2a may be connected to the (1-2)-th semiconductor layer 20a and the cathode electrode CE. The (1-2)-th semiconductor layer 20a and the cathode electrode CE may be electrically connected through the (1-2)-th bonding electrode BDE2a. In one or more embodiments, the (1-2)-th bonding electrode BDE2a may include a eutectic metal.

The first insulating layer 30a may cover at least a portion of an outer peripheral surface of the first light emitting stack EST1. The first insulating layer 30a may be interposed between the (1-2)-th bonding electrode BDE2a and the first active layer MQW1 and between the (1-2)-th bonding electrode BDE2a and the (1-1)-th semiconductor layer 10a, to prevent or reduce an electrical short circuit that may occur if (e.g., when) the (1-2)-th bonding electrode BDE2a contacts the first active layer MQW1 and the (1-1)-th semiconductor layer 10a. The first insulating layer 30a may have a single layer structure or multiple layer structure including a transparent insulating material, for example, silicon oxide, silicon nitride, silicon oxynitride, and/or the like.

The first light extraction structure LES1 may be arranged on the pixel circuit layer PCL to cover the first light emitting element LD1. The first light extraction structure LES1 may directly contact the entire side surface and the entire upper surface of the first light emitting element LD1.

In one or more embodiments, the first light extraction structure LES1 may include a first overcoating layer OCL1 and a first light extraction layer NOC1 arranged on the first overcoating layer OCL1.

The first overcoating layer OCL1 may directly contact at least a portion of a lower surface of the first light emitting element LD1. The first overcoating layer OCL1 may directly contact a portion of a side surface of the first light emitting element LD1 adjacent to a lower surface of the first light emitting element LD1. The first light emitting element LD1 may be partially buried in the first overcoating layer OCL1. The first overcoating layer OCL1 may fix the first light emitting element LD1 bonded to the first anode electrode AE1 and the cathode electrode CE so that the first light emitting element LD1 does not move. The first overcoating layer OCL1 may include at least one of an inorganic insulating layer or an organic insulating layer. For example, the first overcoating layer OCL1 may include epoxy, but embodiments are not limited thereto.

The first light extraction layer NOC1 may directly contact the entire upper surface of the first light emitting element LD1. The first light extraction layer NOC1 may directly contact a surface that does not contact the first overcoating layer OCL1 in the side surface of the first light emitting element LD1. The first light extraction layer NOC1 may include a transparent insulating material.

The cover layer CVL may cover the first light extraction structure LES1 and the pixel circuit layer PCL. The cover layer CVL may include, for example, an inorganic insulating layer including an inorganic material.

The first reflective layer RFL1 may be around (e.g., surround) a side surface of the first light extraction structure LES1. The cover layer CVL may be interposed between the first refractive layer RFL1 and the side surface of the first light extraction structure LES1. The first reflective layer RFL1 may include (e.g., be composed of) a material suitable for reflecting light. Accordingly, light emission efficiency of the first light emitting element LD1 may be improved. In one or more embodiments, the first reflective layer RFL1 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), or an alloy of two or more materials selected from among them. However, embodiments are not limited thereto.

The light functional layer LFL may be arranged on the cover layer CVL and the first reflective layer RFL1. The light functional layer LFL may include a third passivation layer PSV3 and a color filter layer CFL.

The third passivation layer PSV3 may cover the cover layer CVL and the first reflective layer RFL1. The third passivation layer PSV3 may include the same material as one of the first and second passivation layers PSV1 and PSV2. For example, the first passivation layer PSV1, the second passivation layer PSV2, and the third passivation layer PSV3 includes the same material. The third passivation layer PSV3 may provide a flat upper surface.

The color filter layer CFL may be arranged on the third passivation layer PSV3. The color filter layer CFL may include a first color filter CF1 and light blocking patterns LBP. The first color filter CF1 may be configured to selectively transmit light of a desired or suitable wavelength range. For example, the first color filter CF1 may selectively transmit light of a red color. The light blocking patterns LBP may include at least one of one or more suitable types (kinds) of light blocking materials.

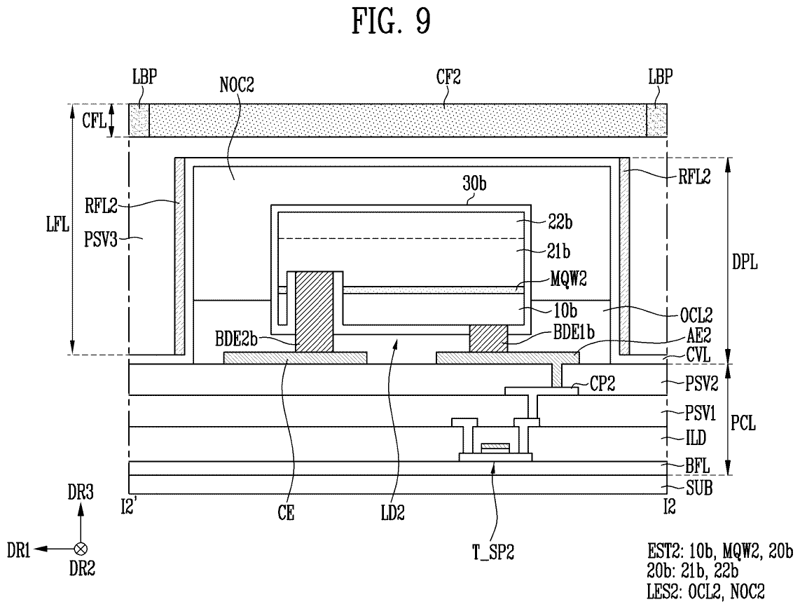

FIG. 9 is a cross-sectional view taken along the line 12-12′ of FIG. 7. FIG. 9 is a cross-sectional view illustrating the second sub-pixel.

Referring to FIGS. 6, 7, and 9, the pixel circuit layer PCL, the display element layer DPL, and the light functional layer LFL may be sequentially arranged on the substrate SUB.

The pixel circuit layer PCL may be described similarly to that described with reference to FIG. 8. For example, the pixel circuit layer PCL may include a second transistor T_SP2 configuring the pixel circuit SPC of the second sub-pixel SP2 and a second connection pattern CP2 connected thereto.

The display element layer DPL may be arranged on the pixel circuit layer PCL. The display element layer DPL may include the second anode electrode AE2, the cathode electrode CE, the second light emitting element LD2, the second light extraction structure LES2, the cover layer CVL, and a second reflective layer RFL2.

The second anode electrode AE2 may be arranged on the pixel circuit layer PCL. The second anode electrode AE2 may be electrically connected to the second connection pattern CP2 through a contact hole passing through the second passivation layer PSV2. As described above, the second anode electrode AE2 may be electrically connected to the second transistor T_SP2.

The second light emitting element LD2 may be arranged on the second anode electrode AE2 and the cathode electrode CE. The second light emitting element LD2 may include a second light emitting stack EST2, a (2-1)-th bonding electrode BDE1b, a (2-2)-th bonding electrode BDE2b, and a second insulating layer 30b.

The second light emitting stack EST2 may be configured to be suitable for emitting the light of the second color. The second light emitting stack EST2 may include a (2-1)-th semiconductor layer 10b, a second active layer MQW2, and a (2-2)-th semiconductor layer 20b.

The (2-1)-th semiconductor layer 10b may be configured to provide a hole. The (2-1)-th semiconductor layer 10b may have a first polarity. For example, the (2-1)-th semiconductor layer 10b may include at least one p-type (kind) semiconductor layer. For example, the (2-1)-th semiconductor layer 10b may include at least one semiconductor material selected from among gallium nitride (GaN), aluminum gallium nitride (AlGaN), indium gallium nitride (InGaN), aluminum nitride (AlN), and indium nitride (InN), and may be a p-type (kind) semiconductor layer doped with a first conductive dopant (or a p-type (kind) dopant) such as magnesium (Mg), zinc (Zn), calcium (Ca), strontium (Sr), and barium (Ba). However, a material configuring the (2-1)-th semiconductor layer 10b is not limited thereto, and one or more suitable other materials may configure the (2-1)-th semiconductor layer 10b. In one or more embodiments of the disclosure, the (2-1)-th semiconductor layer 10b may include a gallium nitride (GaN) semiconductor material doped with the first conductive dopant (or the p-type (kind) dopant).

The second active layer MQW2 may be arranged on the (2-1)-th semiconductor layer 10b. The second active layer MQW2 may be interposed between the (2-1)-th semiconductor layer 10b and the (2-2)-th semiconductor layer 20b to provide an area where an electron and a hole recombine. As the electron and the hole recombine in the second active layer MQW2, the electron and the hole may transition to a low energy level, and thus light having a wavelength corresponding thereto may be generated. The second active layer MQW2 may be formed as a single or multiple quantum well structure. When the second active layer MQW2 is formed as the multiple quantum well structure, a unit including a barrier layer, a strain reinforcement layer, and a well layer may be repeatedly stacked to form the second active layer MQW2. However, the second active layer MQW2 is not limited to the structure described above.

In one or more embodiments, the second active layer MQW2 may be configured to emit the light of the second color (for example, green). In this case, the second active layer MQW2 may include a material suitable for emitting the light of the second color.

The (2-2)-th semiconductor layer 20b may be arranged on the second active layer MQW2. The (2-2)-th semiconductor layer 20b may include a second doping layer 21b and a second auxiliary layer 22b arranged on the second doping layer 21b.

The second doping layer 21b may be arranged on the second active layer MQW2. The second doping layer 21b may be configured to provide an electron. The second doping layer 21b may have a second polarity. For example, the second doping layer 21b may include at least one n-type (kind) semiconductor layer. For example, the second doping layer 21b may include at least one semiconductor material selected from among gallium nitride (GaN), aluminum gallium nitride (AlGaN), indium gallium nitride (InGaN), aluminum nitride (AlN), and indium nitride (InN), and may be an n-type (kind) semiconductor layer doped with a second conductive dopant (or an n-type (kind) dopant) such as silicon (Si), germanium (Ge), and tin (Sn). However, a material configuring the second doping layer 21b is not limited thereto, and one or more suitable other materials may configure the second doping layer 21b. In one or more embodiments of the disclosure, the second doping layer 21b may include a gallium nitride (GaN) semiconductor material doped with the second conductive dopant (or the n-type (kind) dopant).

The second auxiliary layer 22b may include a gallium nitride (GaN) semiconductor material that is not substantially doped with an impurity or is doped with an impurity at a relatively low concentration. The second auxiliary layer 22b may configure an n-type (kind) semiconductor layer together with the second doping layer 21b.

The (2-1)-th bonding electrode BDE1b may be bonded and fixed on the second anode electrode AE2. The (2-1)-th bonding electrode BDE1b may be connected to the (2-1)-th semiconductor layer 10b and the second anode electrode

AE2. The (2-1)-th semiconductor layer 10b and the second anode electrode AE2 may be electrically connected through the (2-1)-th bonding electrode BDE1b. In one or more embodiments, the (2-1)-th bonding electrode BDE1b may include a eutectic metal.

The (2-2)-th bonding electrode BDE2b may be bonded and fixed on the cathode electrode CE. The (2-2)-th bonding electrode BDE2b may be connected to the (2-2)-th semiconductor layer 20b and the cathode electrode CE. The (2-2)-th semiconductor layer 20b and the cathode electrode CE may be electrically connected through the (2-2)-th bonding electrode BDE2b. In one or more embodiments, the (2-2)-th bonding electrode BDE2b may include a eutectic metal.

The second insulating layer 30b may cover at least a portion of an outer peripheral surface of the second light emitting stack EST2. The second insulating layer 30b may be interposed between the (2-2)-th bonding electrode BDE2b and the second active layer MQW2 and between the (2-2)-th bonding electrode BDE2b and the (2-1)-th semiconductor layer 10b, to prevent or reduce an electrical short circuit that may occur if (e.g., when) the (2-2)-th bonding electrode BDE2b contacts the second active layer MQW2 and the (2-1)-th semiconductor layer 10b. The second insulating layer 30b may have a single layer structure or multiple layer structure including a transparent insulating material, for example, silicon oxide, silicon nitride, silicon oxynitride, and/or the like.

The second light extraction structure LES2 may be arranged on the pixel circuit layer PCL to cover the second light emitting element LD2. The second light extraction structure LES2 may directly contact the entire side surface and the entire upper surface of the second light emitting element LD2.

In one or more embodiments, the second light extraction structure LES2 may include a second overcoating layer OCL2 and a second light extraction layer NOC2 arranged on the second overcoating layer OCL2.

The second overcoating layer OCL2 may directly contact at least a portion of a lower surface of the second light emitting element LD2. The second overcoating layer OCL2 may directly contact a portion of a side surface of the second light emitting element LD2 adjacent to the lower surface of the second light emitting element LD2. The second light emitting element LD2 may be partially buried in the second overcoating layer OCL2. The second overcoating layer OCL2 may fix the second light emitting element LD2 bonded to the second anode electrode AE2 and the cathode electrode CE so that the second light emitting element LD2 does not move. The second overcoating layer OCL2 may include the same material as the first overcoating layer OCL1. That is, the first overcoating layer OCL1 and the second overcoating layer OCL2 include the same material.

The second light extraction layer NOC2 may directly contact the entire upper surface of the second light emitting element LD2. The second light extraction layer

NOC2 may directly contact a surface that does not contact the second overcoating layer OCL2 in the side surface of the second light emitting element LD2. The second light extraction layer NOC2 may include the same material as the first light extraction layer NOC1. That is, the first light extraction layer NOC1 and the second light extraction layer NOC2 include the same material.

The cover layer CVL may cover the second light extraction structure LES2 and the pixel circuit layer PCL.

The second reflective layer RFL2 may be around (e.g., surround) a side surface of the second light extraction structure LES2. The cover layer CVL may be interposed between the second reflective layer RFL2 and the side surface of the second light extraction structure LES2. The second reflective layer RFL2 may be spaced and/or apart (e.g., spaced apart or separated) from the first reflective layer RFL1. The second reflective layer RFL2 may include the same material as the first reflective layer RFL1. That is, the first reflective material RFL1 and the second reflective layer RFL2 include the same material.

The light functional layer LFL may be arranged on the cover layer CVL and the second reflective layer RFL2. The light functional layer LFL may include a third passivation layer PSV3 and a color filter layer CFL.

The third passivation layer PSV3 may cover the cover layer CVL and the second reflective layer RFL2. The third passivation layer PSV3 may provide a flat upper surface.

The color filter layer CFL may be arranged on the third passivation layer PSV3. The color filter layer CFL may include a second color filter CF2 and light blocking patterns LBP. The second color filter CF2 may be configured to selectively transmit light of a desired or suitable wavelength range. For example, the second color filter CF2 may be configured to selectively transmit light of a green color. The light blocking patterns LBP may include at least one of one or more suitable types (kinds) of light blocking materials.

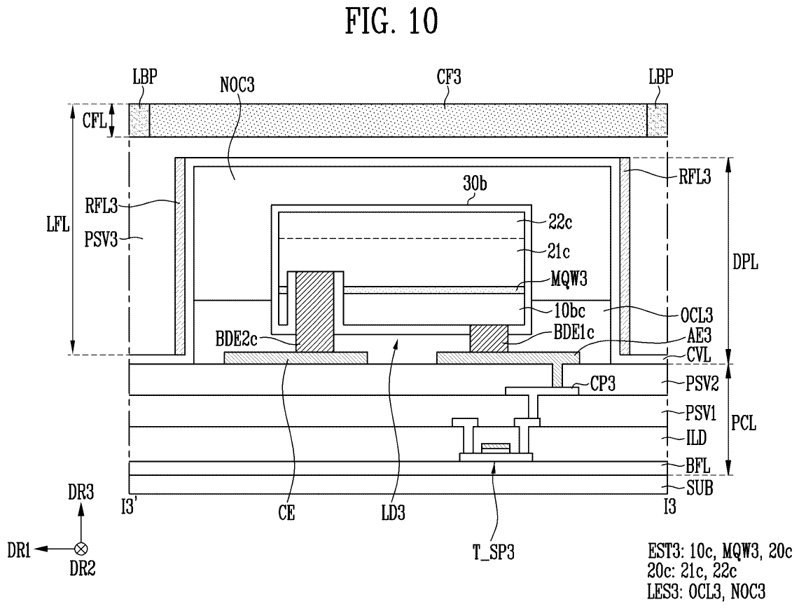

FIG. 10 is a cross-sectional view taken along the line 13-13′ of FIG. 7. FIG. 10 is a cross-sectional view illustrating the third sub-pixel.

Referring to FIGS. 6, 7, and 10, the pixel circuit layer PCL, the display element layer DPL, and the light functional layer LFL may be sequentially arranged on the substrate SUB.

The pixel circuit layer PCL may be described similarly to that described with reference to FIG. 8. For example, the pixel circuit layer PCL may include a third transistor T_SP3 configuring the sub-pixel circuit SPC of the third sub-pixel SP3, and a third connection pattern CP3 connected thereto.

The display element layer DPL may be arranged on the pixel circuit layer. The display element layer DPL may include the third anode electrode AE3, the cathode electrode CE, the third light emitting element LD3, the third light extraction structure LES3, the cover layer CVL, and a third reflective layer RFL3.

The third anode electrode AE3 may be arranged on the pixel circuit layer PCL. The third anode electrode AE3 may be electrically connected to the third connection pattern CP3 through a contact hole passing through the third passivation layer PSV2. As described above, the third anode electrode AE3 may be electrically connected to the third transistor T_SP3.

The third light emitting element LD3 may be arranged on the third anode electrode AE3 and the cathode electrode CE. The third light emitting element LD3 may include a third light emitting stack EST3, a (3-1)-th bonding electrode BDE1c, a (3-2)-th bonding electrode BDE2c, and a third insulating layer 30c.

The third light emitting stack EST3 may be configured to be suitable for emitting the light of the third color. The third light emitting stack EST3 may include a (3-1)-th semiconductor layer 10c, a third active layer MQW3, and a (3-2)-th semiconductor layer 20c.

The (3-1)-th semiconductor layer 10c may be configured to provide a hole. The (3-1)-th semiconductor layer 10c may have a first polarity. For example, the (3-1)-th semiconductor layer 10c may include at least one p-type (kind) semiconductor layer. For example, the (3-1)-th semiconductor layer 10c may include at least one semiconductor material selected from among gallium nitride (GaN), aluminum gallium nitride (AlGaN), indium gallium nitride (InGaN), aluminum nitride (AlN), and indium nitride (InN), and may be a p-type (kind) semiconductor layer doped with a first conductive dopant (or a p-type (kind) dopant) such as magnesium (Mg), zinc (Zn), calcium (Ca), strontium (Sr), and barium (Ba). However, a material configuring the (3-1)-th semiconductor layer 10c is not limited thereto, and one or more suitable other materials may configure the (3-1)-th semiconductor layer 10c. In one or more embodiments of the disclosure, the (3-1)-th semiconductor layer 10c may include a gallium nitride (GaN) semiconductor material doped with the first conductive dopant (or the p-type (kind) dopant).

The third active layer MQW3 may be arranged on the (3-1)-th semiconductor layer 10c. The third active layer MQW3 may be interposed between the (3-1)-th semiconductor layer 10c and the (3-2)-th semiconductor layer 20c to provide an area where an electron and a hole recombine. As the electron and the hole recombine in the third active layer MQW3, the electron and the hole may transition to a low energy level, and thus light having a wavelength corresponding thereto may be generated. The third active layer MQW3 may be formed as a single or multiple quantum well structure. When the third active layer MQW3 is formed as the multiple quantum well structure, a unit including a barrier layer, a strain reinforcement layer, and a well layer may be repeatedly stacked to form the third active layer MQW3. However, the third active layer MQW3 is not limited to the structure described above.

In one or more embodiments, the third active layer MQW3 may be configured to emit the light of the third color (for example, blue). In this case, the third active layer MQW3 may include a material suitable for emitting the light of the third color.

The (3-2)-th semiconductor layer 20c may be arranged on the third active layer MQW3. The (3-2)-th semiconductor layer 20c may include a third doping layer 21c and a third auxiliary layer 22c arranged on the third doping layer 21c.

The third doping layer 21c may be arranged on the third active layer MQW3. The third doping layer 21c may be configured to provide an electron. The third doping layer 21c may have a second polarity. For example, the third doping layer 21c may include at least one n-type (kind) semiconductor layer. For example, the third doping layer 21c may include at least one semiconductor material selected from among gallium nitride (GaN), aluminum gallium nitride (AlGaN), indium gallium nitride (InGaN), aluminum nitride (AlN), and indium nitride (InN), and may be an n-type (kind) semiconductor layer doped with a second conductive dopant (or an n-type (kind) dopant) such as silicon (Si), germanium (Ge), and tin (Sn). However, a material configuring the third doping layer 21c is not limited thereto, and one or more suitable other materials may configure the third doping layer 21c. In one or more embodiments of the disclosure, the third doping layer 21c may include a gallium nitride (GaN) semiconductor material doped with the second conductive dopant (or the n-type (kind) dopant).

The third auxiliary layer 22c may include a gallium nitride (GaN) semiconductor material that is not substantially doped with an impurity or is doped with an impurity at a relatively low concentration. The third auxiliary layer 22c may configure an n-type (kind) semiconductor layer together with the third doping layer 21c.

The (3-1)-th bonding electrode BDE1c may be bonded and fixed on the third anode electrode AE3. The (3-1)-th bonding electrode BDE1c may be connected to the (3-1)-th semiconductor layer 10c and the third anode electrode AE3. The (3-1)-th semiconductor layer 10c and the third anode electrode AE3 may be electrically connected through the (3-1)-th bonding electrode BDE1c. In one or more embodiments, the (3-1)-th bonding electrode BDE1b may include a eutectic metal. The (3-2)-th bonding electrode BDE2c may be bonded and fixed on the cathode electrode CE. The (3-2)-th bonding electrode BDE2c may be connected to the (3-2)-th semiconductor layer 20c and the cathode electrode CE. The (3-2)-th semiconductor layer 20c and the cathode electrode CE may be electrically connected through the (3-2)-th bonding electrode BDE2c. In one or more embodiments, the (3-2)-th bonding electrode BDE2c may include a eutectic metal.

The third insulating layer 30c may cover at least a portion of an outer peripheral surface of the third light emitting stack EST3. The third insulating layer 30c may be interposed between the (3-2)-th bonding electrode BDE2c and the third active layer MQW3 and between the (3-2)-th bonding electrode BDE2c and the (3-1)-th semiconductor layer 10c, to prevent or reduce an electrical short circuit that may occur if (e.g., when) the (3-2)-th bonding electrode BDE2c contacts the third active layer MQW3 and the (3-1)-th semiconductor layer 10c. The third insulating layer 30c may have a single layer structure or multiple layer structure including a transparent insulating material, such as silicon oxide, silicon nitride, or silicon oxynitride.

The third light extraction structure LES3 may be arranged on the pixel circuit layer PCL to cover the third light emitting element LD3. The third light extraction structure LES3 may directly contact the entire side surface and the entire upper surface of the third light emitting element LD3.

In one or more embodiments, the third light extraction structure LES3 may include a third overcoating layer OCL3 and a third light extraction layer NOC3 arranged on the third overcoating layer OCL3.

The third overcoating layer OCL3 may directly contact at least a portion of a lower surface of the third light emitting element LD3. The third overcoating layer OCL3 may directly contact a portion of a side surface of the third light emitting element LD3 adjacent to the lower surface of the third light emitting element LD3. The third light emitting element LD3 may be partially buried in the third overcoating layer OCL3. The third overcoating layer OCL3 may fix the third light emitting element LD3 bonded to the third anode electrode AE3 and the cathode electrode CE so that the third light emitting element LD3 does not move. The third overcoating layer OCL3 may include the same material as the first overcoating layer OCL1. That is, the first overcoating layer OCL1 and the third overcoating layer OCL3 include the same material.

The third light extraction layer NOC3 may directly contact the entire upper surface of the third light emitting element LD3. The third light extraction layer NOC3 may directly contact a surface that does not contact the third overcoating layer OCL3 in the side surface of the third light emitting element LD3. The third light extraction layer NOC3 may include the same material as the first light extraction layer NOC1. That is, the first light extraction layer NOC1 and the third light extraction layer NOC3 include the same material.

The cover layer CVL may cover the third light extraction structure LES3 and the pixel circuit layer PCL.

The third reflective layer RFL3 may be around (e.g. surround) a side surface of the third light extraction structure LES3. The cover layer CVL may be interposed between the third reflective layer RFL3 and the side surface of the third light extraction structure LES3. The third reflective layer RFL3 may be spaced and/or apart (e.g., spaced apart or separated) from the first and second reflective layers RFL1 and RFL2. The third reflective layer RFL3 may include the same material as the first reflective layer RFL1. That is, the first reflective layer RFL1 and the third reflective layer RFL3 include the same material.

The light functional layer LFL may be arranged on the cover layer CVL and the third reflective layer RFL3. The light functional layer LFL may include a third passivation layer PSV3 and a color filter layer CFL.

The third passivation layer PSV3 may cover the cover layer CVL and the third reflective layer RFL3. The third passivation layer PSV3 may provide a flat upper surface.

The color filter layer CFL may be arranged on the third passivation layer PSV3. The color filter layer CFL may include a third color filter CF3 and light blocking patterns LBP. The third color filter CF3 may be configured to selectively transmit light of a desired or suitable wavelength range. For example, the third color filter CF3 may be configured to selectively transmit light of a blue color. The light blocking patterns LBP may include at least one of one or more suitable types (kinds) of light blocking materials.

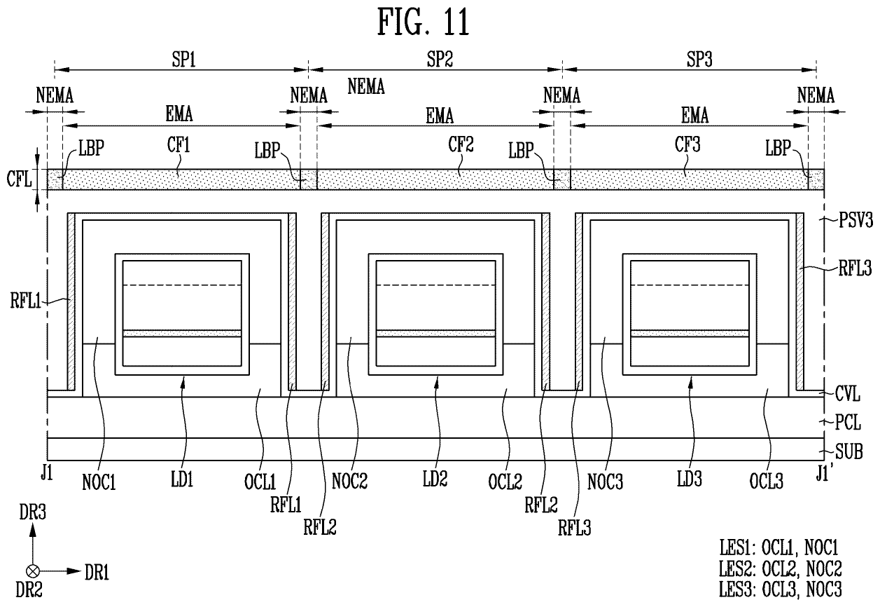

FIG. 11 is a cross-sectional view taken along the line J1-J1′ of FIG. 7.

Referring to FIGS. 6 to 11, the color filter layer CFL may include the first to third color filters CF1, CF2, and CF3, and the light blocking patterns LBP.

Each of the first to third color filters CF1, CF2, and CF3 may be configured to selectively transmit light of a desired or suitable wavelength range. In one or more embodiments, the first color filter CF1 may be a red color filter, the second color filter CF2 may be a green color filter, and the third color filter CF3 may be a blue color filter.

The light blocking patterns LBP may be arranged between the first to third color filters CF1, CF2, and CF3. It may be understood that an emission area (or an light output area) EMA and a non-emission area NEMA for the first to third sub-pixels SP1, SP2, and SP3 are defined by the light blocking patterns LBP. An area overlapping the light blocking patterns LBP may correspond to the non-emission area NEMA. An area that does not overlap the light blocking patterns LBP may correspond to the emission area EMA.

In one or more embodiments, the light blocking patterns LBP may include at least one of one or more suitable types (kinds) of light blocking materials. In one or more embodiments, each of the light blocking patterns LBP may be provided in a form of multiple layers in which at least two color filters selected from among the first to third color filters CF1, CF2, and CF3 overlap. For example, each of the light blocking patterns LBP may be formed by overlapping the first to third color filters CF1, CF2, and CF3. As another example, the light blocking pattern between the first and second color filters CF1 and CF2 among the light blocking patterns LBP may be formed as multiple layers in which the first and second color filters CF1 and CF2 overlap, and the light blocking pattern between the second and third color filters CF2 and CF3 among the light blocking patterns LBP may be formed as multiple layers in which the second and third color filters CF2 and CF3 overlap. The light blocking pattern between the first color filter CF1 and the third color filter CF3 of a neighboring pixel may be formed as multiple layers in which the first and third color filters CF1 and CF3 overlap. As described above, each of the first to third color filters CF1, CF2, and CF3 may be extended to the non-emission area NEMA to form the light blocking patterns LBP.

In the disclosure, the first light extraction structure LES1 may overlap the first light emitting element LD1 as shown in FIG. 7. In this case, the first reflective layer RFL1 around (e.g., surrounding) the side surface of the first light extraction structure LES1 may be arranged to be around (e.g., surround) the first light emitting element LD1, and the cover layer may be interposed between the first reflective layer RFL1 and the side surface of the first light extraction structure LES1. Accordingly, the light of the red color emitted from the first light emitting element LD1 may be reflected by the first reflective layer RFL1 and provided in a direction toward the first color filter CF1. In addition, light mixing occurring if (e.g., when) the light of the red color emitted from the first light emitting element LD1 proceeds to the emission areas EMA of other sub-pixels adjacent to the first sub-pixel SP1 may be prevented or reduced.

The second light extraction structure LES2 may overlap the second light emitting element LD2 as shown in FIG. 7. In this case, the second reflective layer RFL2 around (e.g., surrounding) the side surface of the second light extraction structure LES2 may be arranged to be around (e.g., surround) the second light emitting element LD2, and the cover layer CVL may be interposed between the second reflective layer RFL2 and the side surface of the second light extraction structure LES2. Accordingly, the light of the green color emitted from the second light emitting element LD2 may be reflected by the second reflective layer RFL2 and provided in a direction t toward the second color filter CF2. In addition, light mixing occurring if (e.g., when) the light of the green color emitted from the second light emitting element LD2 proceeds to the emission area EMA of other sub-pixels adjacent to the second sub-pixel SP2 may be prevented or reduced.

The third light extraction structure LES3 may overlap the third light emitting element LD3 as shown in FIG. 7. In this case, the third reflective layer RFL3 around (e.g., surrounding) the side surface of the third light extraction structure LES3 may be arranged to be around (e.g., surround) the third light emitting element LD3, and the cover layer CVL may be interposed between the third reflective layer RFL3 and the side surface of the third light extraction structure LES3. Accordingly, the light of the blue color emitted from the third light emitting element LD3 may be reflected by the third reflective layer RFL3 and provided in a direction toward the third color filter CF3. In addition, light mixing occurring if (e.g., when) the light of blue color emitted from the third light emitting element LD3 proceeds to the emission area EMA of other sub-pixels adjacent to the third sub-pixel SP3 may be prevented or reduced.

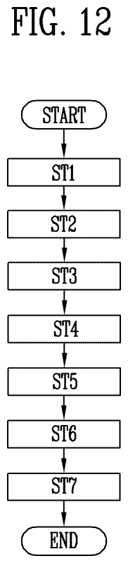

FIG. 12 is a diagram illustrating a method of manufacturing a display device including the pixel of FIGS. 6 and 7.

Referring to FIG. 12, the method of manufacturing the display device may include first to seventh steps ST1, ST2, ST3, ST4, ST5, ST6, and ST7.

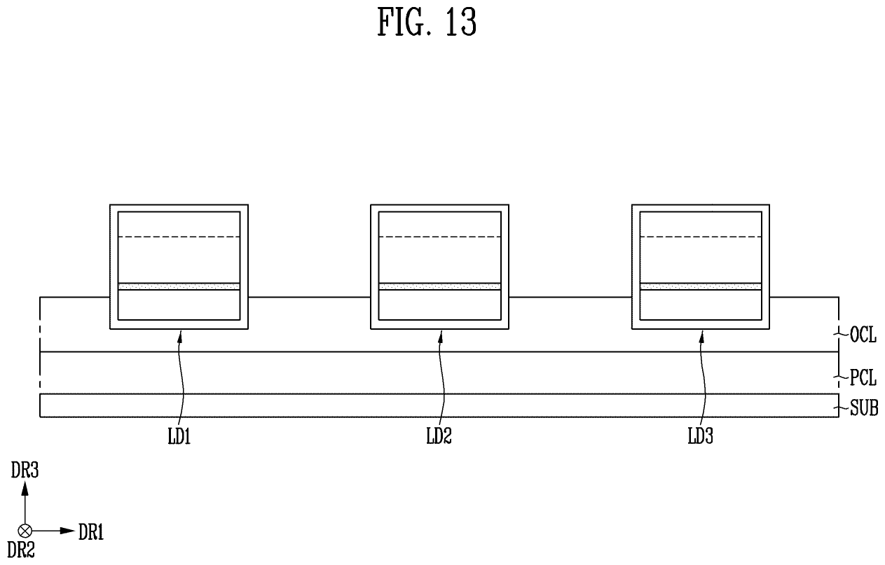

FIGS. 13 to 19 are cross-sectional views illustrating the manufacturing method of FIG. 12. Hereinafter, a description of a content (e.g., amount) that overlaps the content (e.g., amount) described with reference to FIGS. 1 to 11 may not be provided.

Referring to FIG. 13, after forming the first to third light emitting elements LD1, LD2, and LD3 spaced and/or apart (e.g., spaced apart or separated) from each other on the pixel circuit layer PCL, the overcoating layer OCL may be formed to fix the first to third light emitting elements LD1, LD2, and LD3 (ST1).

In this step (e.g., act or task), the first to third light emitting elements LD1, LD2, and LD3 may be formed to be bonded to the first to third anode electrodes AE1, AE2, and AE3 and the cathode electrode CE as described with reference to FIGS. 8 to 10.

After bonding of the first to third light emitting elements LD1, LD2, and LD3 is completed, as the overcoating layer OCL is formed (or applied), the first to third light emitting elements LD1, LD2, and LD3 may be fixed at a preset position. In this case, the first to third light emitting elements LD1, LD2, and LD3 may be partially buried in the overcoating layer OCL.

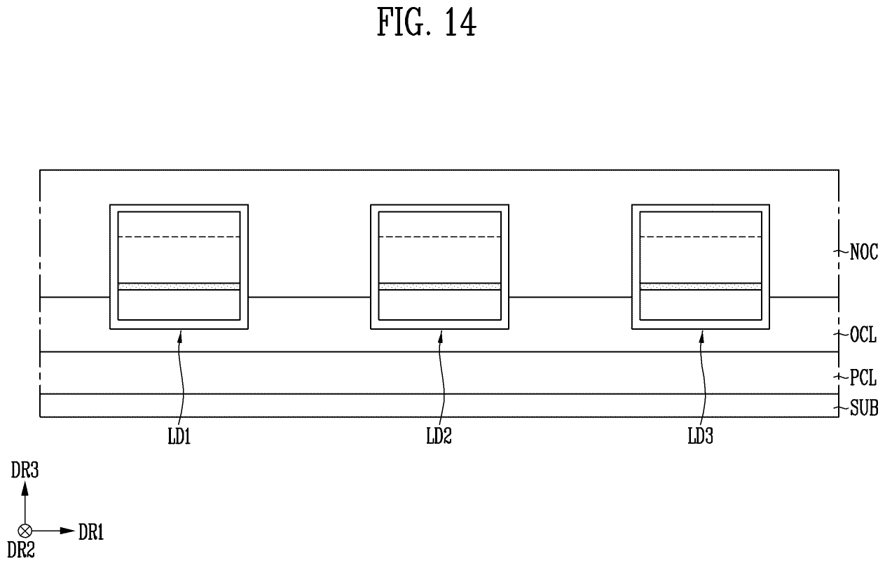

Referring to FIG. 14, the light extraction layer NOC covering the first to third light emitting elements LD1, LD2, and LD3 may be formed on the overcoating layer OCL (ST2). As the light extraction layer NOC is formed, the first to third light emitting elements LD1, LD2, and LD3 may be buried by the light extraction layer NOC.

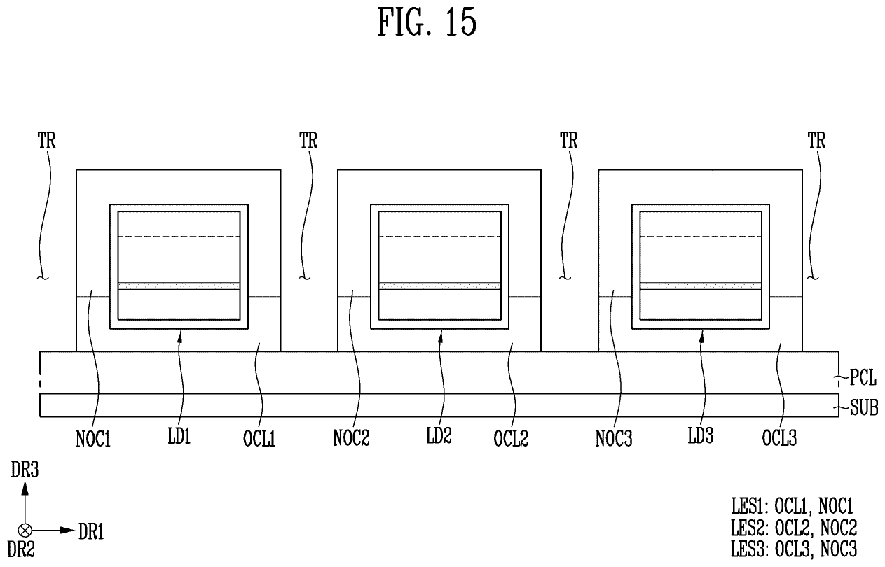

Referring to FIG. 15, the overcoating layer OCL and the light extraction layer NOC may be partially etched to form the first to third light extraction structures LES1, LES2, and LES3 spaced and/or apart (e.g., spaced apart or separated) from each other (ST3). In this step (e.g., act or task), a trench TR may be defined between the first to third light extraction structures LES1, LES2, and LES3.

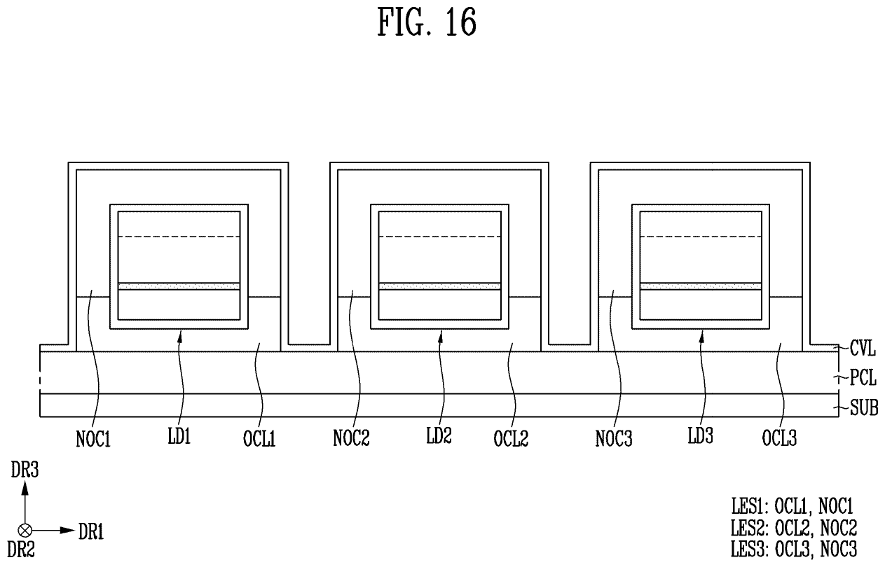

Referring to FIG. 16, the cover layer CVL covering the first to third light extraction structures LES1, LES2, and LES3 and the pixel circuit layer PCL may be formed (ST4). In this step (e.g., act or task), the cover layer CVL may be formed to have a shape corresponding to a cross-sectional profile of the first to third light extraction structures LES1, LES2, and LES3 defining the trench TR.

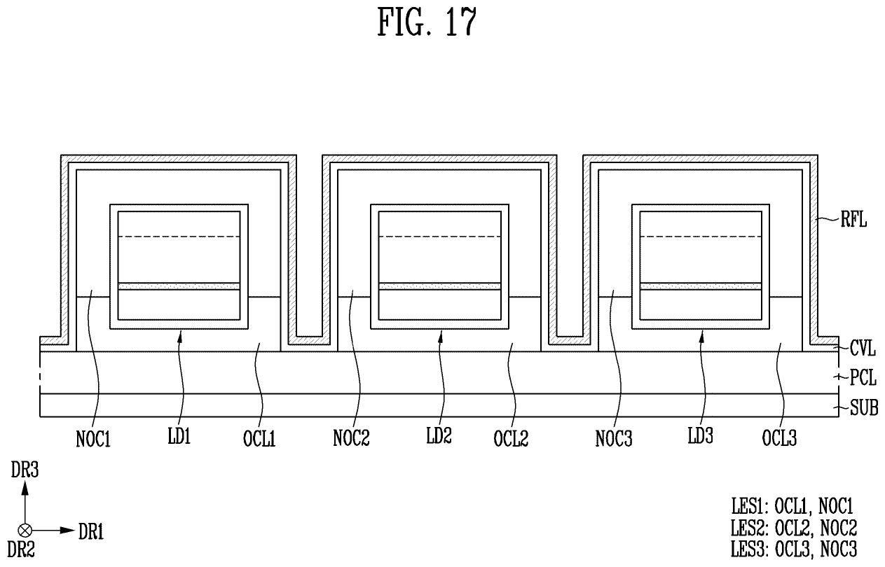

Referring to FIG. 17, the reflective layer RFL covering the cover layer CVL may be formed (ST5). In this step (e.g., act or task), the reflective layer RFL may be formed to have a shape corresponding to a cross-sectional profile of the cover layer CVL.

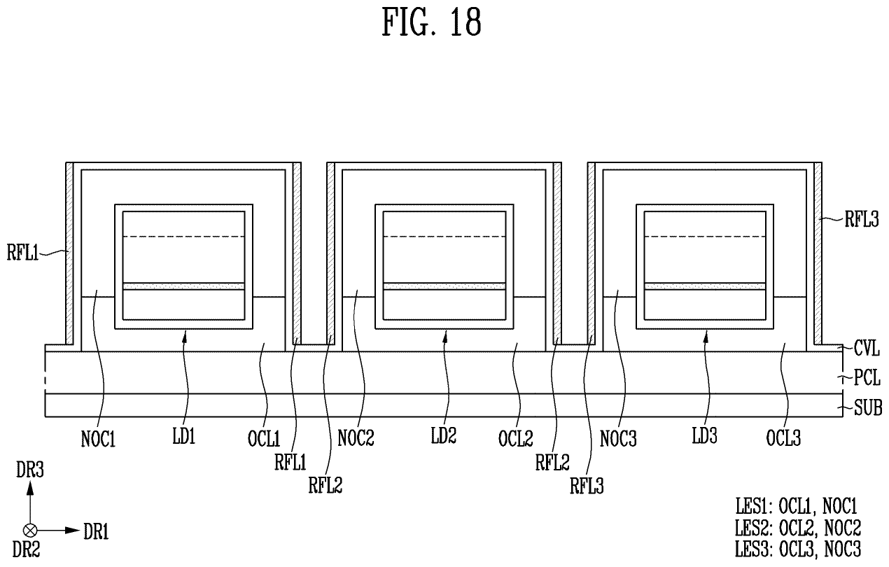

Referring to FIG. 18, the reflective layer RFL may be partially etched to form first to third reflective layers RFL1, RFL2, and RFL3 (ST6).

In this step (e.g., act or task), a portion of the reflective layer RFL overlapping an upper surface of the first to third light extraction structures LES1, LES2, and LES3 may be removed by the etching. In addition, a portion of the reflective layer RFL overlapping a lower surface of the trench TR may be removed by the etching. Accordingly, the first to third reflective layers RFL1, RFL2, and RFL3 may be provided as separate components.

In one or more embodiments, one or more suitable etching methods for forming the first to third reflective layers RFL1, RFL2, and RFL3 described above may be used as the etching without limitation. For example, the etching may be anisotropic dry etching or wet etching.

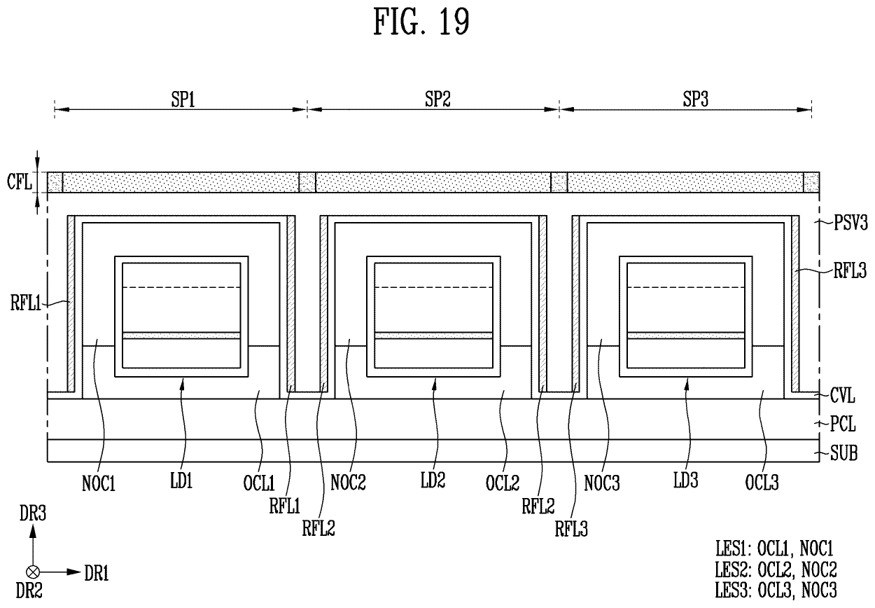

Referring to FIG. 19, the third passivation layer PSV3 and the color filter layer CFL may be formed (ST7). Accordingly, the display device including the first to third sub-pixels SP1, SP2, and SP3 may be provided.

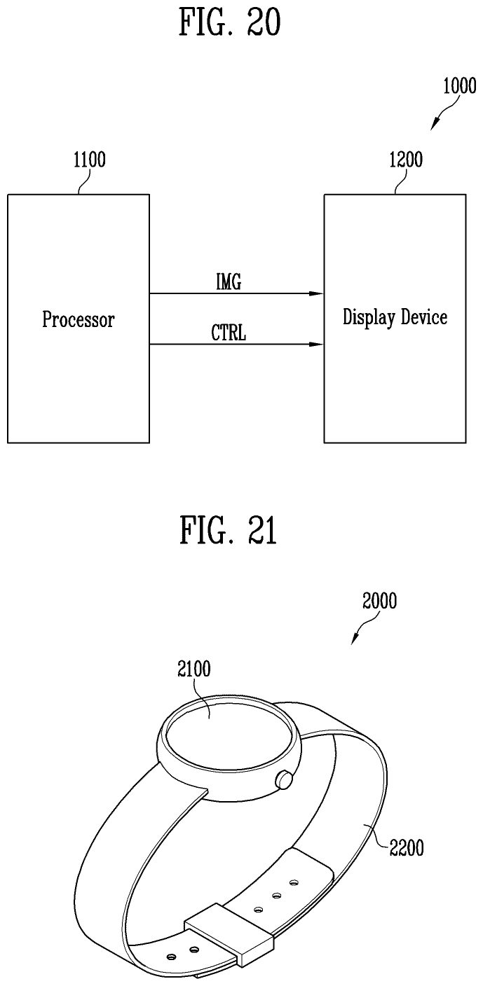

FIG. 20 is a block diagram illustrating a display system according to one or more embodiments.

Referring to FIG. 20, the display system 1000 may include a processor 1100 and a display device 1200.

The processor 1100 may perform one or more suitable tasks and calculations. In one or more embodiments, the processor 1100 may include an application processor, a graphics processor, a microprocessor, a central processing unit (CPU), and/or the like. The processor 1100 may be connected to other components of the display system 1000 through a bus system to control the other components.

The processor 1100 may be configured to transmit image data IMG and a control signal CTRL to the display device 1200. The display device 1200 may display an image based on the image data IMG and the control signal CTRL. The display device 1200 may be configured similarly to the display device DD described with reference to FIG. 1. In this case, the image data IMG and the control signal CTRL may be provided as the input image data IMG and the control signal CTRL of FIG. 1, respectively.

The display system 1000 may include a computing system providing an image display function, such as a smart watch, a mobile phone, a smart phone, a portable computer, a tablet personal computer (PC), a watch phone, an automotive display, smart glasses, a portable multimedia player (PMP), a navigation device, and an ultra mobile personal computer (UMPC). In addition, the display system 1000 may include at least one of a head mounted display (HMD) device, a virtual reality (VR) device, a mixed reality (MR) device, or an augmented reality (AR) device.

FIGS. 21 to 24 are perspective views illustrating application examples of the display system of FIG. 20.

Referring to FIG. 21, the display system 1000 of FIG. 20 may be applied to a smart watch 2000 including a display unit 2100 and a strap unit 2200.

The smart watch 2000 may be a wearable electronic device. For example, the smart watch 2000 may have a structure in which the strap unit 2200 is mounted on a user's wrist. Here, the display system 1000 and/or the display device 1200 may be applied to the display unit 2100, and image data including time information may be provided to a user.

Referring to FIG. 22, the display system 1000 of FIG. 20 may be applied to an automotive display system 3000. Here, the automotive display system 3000 may include a computing system provided inside and/or outside a vehicle to provide image data.

For example, the display system 1000 and/or the display device 1200 may be applied to at least one of an infotainment panel 3100, a cluster 3200, a co-driver display 3300, a head-up display 3400, a side mirror display 3500, or rear seat displays 3600 provided in a vehicle.

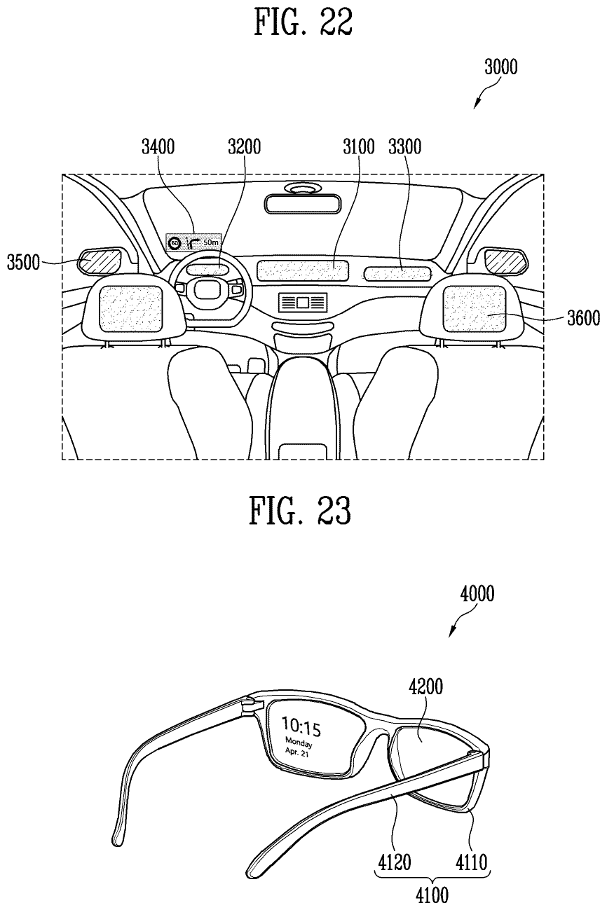

Referring to FIG. 23, the display system 1000 of FIG. 20 may be applied to smart glasses 4000. The smart glasses 4000 may be a wearable electronic device that may be worn on a user's head. For example, the smart glasses 4000 may be a wearable device for augmented reality.

The smart glasses 4000 may include a frame 4100 and a lens unit 4200. The frame 4100 may include a housing 4110 that supports the lens unit 4200 and a leg unit 4120 for the user to wear. The leg unit 4120 may be connected to the housing 4110 through a hinge and may be folded or unfolded relative to the housing 4110.

A battery, a touch pad, a microphone, a camera, and/or the like may be built in the frame 4100. In addition, a projector that outputs light, a processor that controls a light signal, and/or the like may be built in the frame 4100.

The lens unit 4200 may include an optical member that transmits or reflects light. For example, the lens unit 4200 may include glass, transparent synthetic resin, and/or the like.

In order for user's eyes to recognize visual information, the lens unit 4200 may reflect an image by the light signal transmitted from the projector of the frame 4100 by a rear surface (for example, a surface of a direction toward the user's eyes) of the lens unit 4200. For example, the user may recognize visual information such as time and date displayed on the lens unit 4200. At this time, the projector and/or the lens unit 4200 may be a type (kind) of display device. The display device 1200 may be applied to the projector and/or the lens unit 4200.

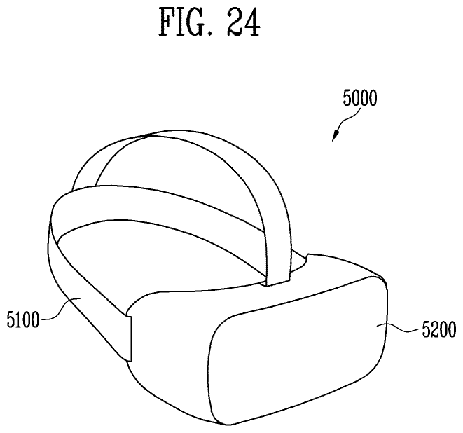

Referring to FIG. 24, the display system 1000 of FIG. 20 may be applied to a head mounted display device 5000.

The head mounted display device 5000 may be a wearable electronic device that may be worn on a user's head. For example, the head mounted display device 5000 may be a wearable device for virtual reality or mixed reality.

The head mounted display device 5000 may include a head mount band 5100 and a display device receiving case 5200. The head mount band 5100 may be connected to the display device receiving case 5200. The head mount band 5100 may include a horizontal band and/or a vertical band for fixing the head mounted display device 5000 to a user's head. The horizontal band may be configured to be around (e.g., surround) a side portion of the user's head, and the vertical band may be configured to be around (e.g., surround) an upper portion of the user's head. However, embodiments are not limited thereto. For example, the head mount band 5100 may be implemented in a form of a glasses frame, a helmet, and/or the like.

The display device receiving case 5200 may receive the display system 1000 and/or the display device 1200.

The display device, the electronic apparatus, the electronic equipment or device, a manufacturing device for the display device, the electronic apparatus, the electronic equipment or device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Although described with reference to the above embodiments, it will be understood that those skilled in the art can variously modify and change the disclosure without departing from the spirit and scope of the disclosure described in the claims and equivalents thereof.

What is claimed is:

1. A display device comprising:
first and second light emitting elements on a pixel circuit layer and spaced from each other;
a first light extraction structure on the pixel circuit layer overlapping the first light emitting element in a plan view;
a second light extraction structure on the pixel circuit layer overlapping the second light emitting element in a plan view, and spaced from the first light extraction structure;
a cover layer covering the first and second light extraction structures and the pixel circuit layer;
a first reflective layer surrounding a side surface of the first light extraction structure, wherein the cover layer is interposed between the first reflective layer and the side surface of the first light extraction structure; and
a second reflective layer surrounding a side surface of the second light extraction structure, wherein the cover layer is interposed between the second reflective layer and the side surface of the second light extraction structure.

2. The display device according to claim 1, wherein the first reflective layer and the second reflective layer are spaced from each other.

3. The display device according to claim 1, wherein in a plan view, an edge of the first light extraction structure is arranged to completely surround an edge of the first light emitting element, and
in a plan view, an edge of the second light extraction structure is arranged to completely surround an edge of the second light emitting element.

4. The display device according to claim 1, wherein the first light emitting element is configured to generate light of a first color, and
the second light emitting element is configured to generate light of a second color different from the first color.

5. The display device according to claim 1, wherein the first light extraction structure directly contacts entire of a side surface of the first light emitting element and directly contacts entire of an upper surface of the first light emitting element, and
the second light extraction structure directly contacts entire of side surfaces of the second light emitting element and directly contacts entire of an upper surface of the second light emitting element.

6. The display device according to claim 1, wherein the first light emitting element comprises a (1-1)-th semiconductor layer, a (1-2)-th semiconductor layer on the (1-1)-th semiconductor layer, and a first active layer interposed between the (1-1)-th semiconductor layer and the (1-2)-th semiconductor layer, and
the second light emitting element comprises a (2-1)-th semiconductor layer, a (2-2)-th semiconductor layer on the (2-1)-th semiconductor layer, and a second active layer interposed between the (2-1)-th semiconductor layer and the (2-2)-th semiconductor layer.

7. The display device according to claim 1, comprising:
a first anode electrode between the first light emitting element and the pixel circuit layer; and
a second anode electrode between the second light emitting element and the pixel circuit layer.

8. The display device according to claim 7, wherein the first light extraction structure is overlapping the first anode electrode in a plan view, and the second light extraction structure is overlapping the second anode electrode in a plan view.

9. The display device according to claim 7, further comprising:
a cathode electrode between the first and second light emitting elements and the pixel circuit layer.

10. The display device according to claim 9, wherein the first light extraction structure is overlapping a portion of the cathode electrode in a plan view, and
the second light extraction structure is overlapping another portion of the cathode electrode in a plan view.

11. The display device according to claim 1, wherein the first light extraction structure comprises a first overcoating layer and a first light extraction layer on the first overcoating layer, and
the second light extraction structure comprises a second overcoating layer and a second light extraction layer on the second overcoating layer.

12. The display device according to claim 11, wherein the first overcoating layer directly contacts at least a portion of a lower surface of the first light emitting element, and
the second overcoating layer directly contacts at least a portion of a lower surface of the second light emitting element.

13. The display device according to claim 1, further comprising:
a third light emitting element on the pixel circuit layer and spaced from the first and second light emitting elements;
a third light extraction structure on the pixel circuit layer overlapping the third light emitting element in a plan view, and spaced from the first and second light extraction structures; and
a third reflective layer surrounding a side surface of the third light extraction structure, wherein the cover layer is interposed between the third reflective layer and the side surface of the third light extraction structure.

14. The display device according to claim 13, wherein a color of light generated by the third light emitting element is different from a color of light generated by the first light emitting element and a color of light generated by the second light emitting element.

15. The display device according to claim 1, further comprising:
a passivation layer covering the cover layer, the first reflective layer, and the second reflective layer; and
a color filter layer on the passivation layer.

16. The display device according to claim 15, wherein an upper surface of the passivation layer is flat.

17. A method of manufacturing a display device, comprising:
forming first and second light extraction structures overlapping the first and second light emitting elements in a plan view on a pixel circuit layer and spaced from each other;
forming a cover layer covering the first and second light extraction structures and the pixel circuit layer; and
forming first and second reflective layers surrounding side surfaces of the first and second light extraction structures, wherein the cover layer is interposed between the first reflective layer and the side surface of the first light extraction structure and between the second reflective layer and the side surface of the second light extraction structure.

18. The method according to claim 17, wherein the forming of the first and second reflective layers comprises:
forming a reflective layer covering the cover layer; and
forming the first and second reflective layers by partially etching the reflective layer.

19. The method according to claim 17, wherein the forming of the first and second light extraction structures comprises:
forming the first and second light emitting elements spaced from each other on the pixel circuit layer;
forming an overcoating layer on the pixel circuit layer;
forming a light extraction layer covering the first and second light emitting elements on the overcoating layer; and
forming the first and second light extraction structures by partially etching the overcoating layer and the light extraction layer.

20. The method according to claim 19, wherein in the forming of the overcoating layer, the first and second light emitting elements are partially buried in the overcoating layer.

21. An electronic device comprising:
a processor to provide input image data; and
a display device to display an image based on the input image data,
wherein the display device comprising:
first and second light emitting elements on a pixel circuit layer and spaced from each other;
a first light extraction structure on the pixel circuit layer overlapping the first light emitting element in a plan view;
a second light extraction structure on the pixel circuit layer overlapping the second light emitting element in a plan view, and spaced from the first light extraction structure;
a cover layer covering the first and second light extraction structures and the pixel circuit layer;
a first reflective layer surrounding a side surface of the first light extraction structure, wherein the cover layer is interposed between the first reflective layer and the side surface of the first light extraction structure; and
a second reflective layer surrounding a side surface of the second light extraction structure, wherein the cover layer is interposed between the second reflective layer and the side surface of the second light extraction structure.
